(19) United States
(12) Patent Application Publication
(10) Pub. No.: US 2025/0072231 A1
(43) Pub. Date: Feb. 27, 2025

(54) LIGHT CONTROLLING PANEL AND TRANSPARENT DISPLAY DEVICE INCLUDING THE SAME

(71) Applicant: LG Display Co., Ltd., Seoul (KR)

(72) Inventors: DongIl YU, Paju-si (KR); KyoungSang YOON, Paju-si (KR); Youngki SONG, Paju-si (KR)

(73) Assignee: LG Display Co., Ltd., Seoul (KR)

(21) Appl. No.: 18/805,808

(22) Filed: Aug. 15, 2024

(30) Foreign Application Priority Data
Aug. 25, 2023 (KR) 10-2023-0112015

(51) Int. Cl. H10K 59/127; H10K 59/80; H10K 102/00

(52) U.S. Cl. CPC H10K 59/127; H10K 59/80524; H10K 2102/3031; H10K 2102/351

(57) ABSTRACT

A light controlling panel may include a first electrode and a second electrode disposed to face each other, and a dielectric layer disposed between the first electrode and the second electrode. The dielectric layer may include a first dielectric including a first dielectric material and a groove, the first dielectric material having a first dielectric permittivity, and a second dielectric including a plurality of light blocking particles and a solvent including a second dielectric material having a second dielectric permittivity less than the first dielectric permittivity. The first dielectric may include a first dielectric pattern disposed between adjacent grooves. The first dielectric may also include a protrusion where a portion of a top surface of the first dielectric pattern protrudes toward the second electrode.

### CROSS-REFERENCE TO RELATED APPLICATIONS

This application claims the benefit of and priority to Korean Patent Application No. 10-2023-0112015, filed in the Republic of Korea on Aug. 25, 2023, the entirety of which is incorporated herein by reference for all purposes.

### BACKGROUND

### 1. Technical Field

The present disclosure relates to display apparatuses, and particularly to, for example, without limitation, a light controlling panel and a transparent display device including the light controlling panel. In more detail, the present disclosure relates to an light controlling panel and a transparent display device capable of improving display quality.

### 2. Discussion of the Related Art

With advancement in information-oriented societies, demands for display devices that display images have increased in various forms. Recently, various types of display devices such as a liquid crystal display (LCD) device, a plasma display panel (PDP) device, a Quantum dot Light Emitting Display (QLED), and an organic light emitting display (OLED) device have been widely utilized.

In particular, the organic light emitting display (OLED) devices are attracting attention as next-generation display devices because they are not only advantageous in terms of power consumption due to low-voltage operation, but also in terms of color reproduction, response speed, viewing angle, and contrast ratio.

Active research is currently underway on display devices that have a transmissive area to allow external light to pass through them, such that a background scene located behind the transparent display device or objects or images located on the rear surface of the transparent display device can be viewed through the transparent display device.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and needs of the related art, have performed extensive research and experiments, and have developed a new invention. The inventors have invented display apparatuses having new structures, and in particular, a new light controlling panel and a new transparent display device including the light controlling panel. One or more aspects of the present disclosure are directed to an apparatus that substantially obviates one or more problems due to limitations and disadvantages of the related art.

In one or more aspects, the present disclosure is directed to providing a light controlling panel and a transparent display device including the light controlling panel capable of implementing a light-blocking mode that blocks light and a light-transmitting mode that transmits light.

An aspect of the present disclosure is directed to a light controlling panel and a transparent display device including the light controlling panel that can selectively implement a light-blocking mode that blocks light to improve display clarity and a light-transmitting mode that transmits light to allow the background scene of the display panel to be visually recognized.

Another aspect of the present disclosure is directed to a light controlling panel and a transparent display device including the light controlling panel capable of improving light transmittance in the light-transmitting mode.

Another aspect of the present disclosure is directed to a light controlling panel and a transparent display device including the light controlling panel capable of increased longevity, thereby improving ESG (Environment/Social/Governance) qualities by increasing the lifespan of display devices and reducing the generation of greenhouse gases associated with the manufacturing process of display devices.

Additional aspects, advantages and features of the present disclosure will be set forth in part in the description which follows and in part will become apparent to those having ordinary skill in the art upon examination of the present disclosure or can be learned from practice of the present disclosure. Other aspects, advantages and features of the present disclosure can be realized and attained by the descriptions provided in the present disclosure, including the claims and the drawings.

To achieve these and other advantages and aspects of the present disclosure, as embodied and broadly described herein, in one or more aspects, there is provided a light controlling panel including a first electrode and a second electrode disposed to face each other, and a dielectric layer disposed between the first electrode and the second electrode, wherein the dielectric layer includes a first dielectric including a first dielectric material and a groove, the first dielectric material having a first dielectric permittivity, and a second dielectric including a plurality of light blocking particles and a solvent including a second dielectric material having a second dielectric permittivity less than the first dielectric permittivity, wherein the first dielectric comprises a first dielectric pattern disposed between adjacent grooves, and wherein the first dielectric further comprises a protrusion where a portion of a top surface of the first dielectric pattern protrudes toward the second electrode.

In one or more aspects of the present disclosure, there is a transparent display device including a transparent display panel including a transmissive area for transmitting an external light and a non-transmissive area in which a plurality of pixels are disposed, and a light controlling panel including a first electrode, a second electrode, and a dielectric layer disposed between the first electrode and the second electrode, wherein the dielectric layer includes a first dielectric including a first dielectric material having a first dielectric permittivity, the first dielectric further including a groove, and a second dielectric including a plurality of light blocking particles and a solvent including a second dielectric material having a second dielectric permittivity less than the first dielectric permittivity, wherein the first dielectric comprises a first dielectric pattern disposed between adjacent grooves, and wherein the first dielectric further comprises a protrusion where a portion of a top surface of the first dielectric pattern protrudes toward the second electrode.

In one or more aspects of the present disclosure, there is a transparent display device comprising a transparent display panel including a transmissive area for transmitting an external light and a non-transmissive area at which a plurality of pixels are disposed, and a light controlling panel including a dielectric layer, wherein the dielectric layer comprises a plurality of light blocking particles that are movable, wherein the light controlling panel is configured to operate in a light-blocking mode or a light-transmitting mode, and wherein for the light-transmitting mode, the light controlling panel is configured to cause the plurality of light blocking particles to move into an area corresponding to the non-transmissive area.

According to one or more aspects of the present disclosure, the protrusion has an inclined side surface of a regular tapered shape.

According to one or more aspects of the present disclosure, the protrusion has a flat top surface.

According to one or more aspects of the present disclosure, a horizontal distance between a first point of the top surface of the first dielectric pattern and a second point of a top surface of the protrusion is less than a vertical distance which is a height of the protrusion, the first point is a point where the top surface of the first dielectric pattern and one end of a side surface of the protrusion meet, and the second point is a point where the top surface of the protrusion and the other end of the side surface of the protrusion meet.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a perspective view illustrating a transparent display device according to one or more example embodiments of the present disclosure;

FIG. 2 is a plan view illustrating a transparent display panel according to one or more example embodiments of the present disclosure;

FIG. 3 is a diagram illustrating an example of a transmissive area and a non-transmissive area provided in the display area of FIG. 2;

FIG. 4 is an example of a circuit diagram of a sub-pixel illustrated in FIG. 3;

FIG. 5 is an example of a cross-sectional view illustrating an example of I-I′ of FIG. 3;

FIG. 6 is a perspective view illustrating a light controlling panel according to one or more example embodiments of the present disclosure;

FIG. 7 is a cross-sectional view illustrating an example of one side of FIG. 6 in a light-blocking mode;

FIG. 8 is a cross-sectional view illustrating an example of an arrangement relationship between components of a transparent display panel and components of the light controlling panel;

FIG. 9 is a cross-sectional view illustrating an example of one side of FIG. 6 in a light-transmitting mode;

FIG. 10 is a plan view illustrating an example of a spacer, a first dielectric pattern, and a groove illustrated in FIG. 9;

FIG. 11 is an example of an enlarged view of portion PT illustrated in FIG. 9;

FIG. 12A is a diagram for explaining polarization density according to an experimental example;

FIG. 12B is a diagram for explaining polarization density according to an example embodiment of the present disclosure;

FIG. 13 is a cross-sectional view illustrating another example of one side of FIG. 6 in a light-blocking mode;

FIG. 14 is a cross-sectional view illustrating another example of one side of FIG. 6 in a light-blocking mode;

FIG. 15 is a cross-sectional view illustrating another example of one side of FIG. 6 in a light-transmitting mode; and

FIG. 16 is a plan view illustrating another example of a spacer, a first dielectric pattern, and a groove illustrated in FIG. 14.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like (or the terms such as a row direction, a column direction, an X-axis direction, a Y-axis direction, and a Z-axis direction) should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

FIG. 1 is a perspective view illustrating a transparent display device according to one or more example embodiments of the present disclosure.

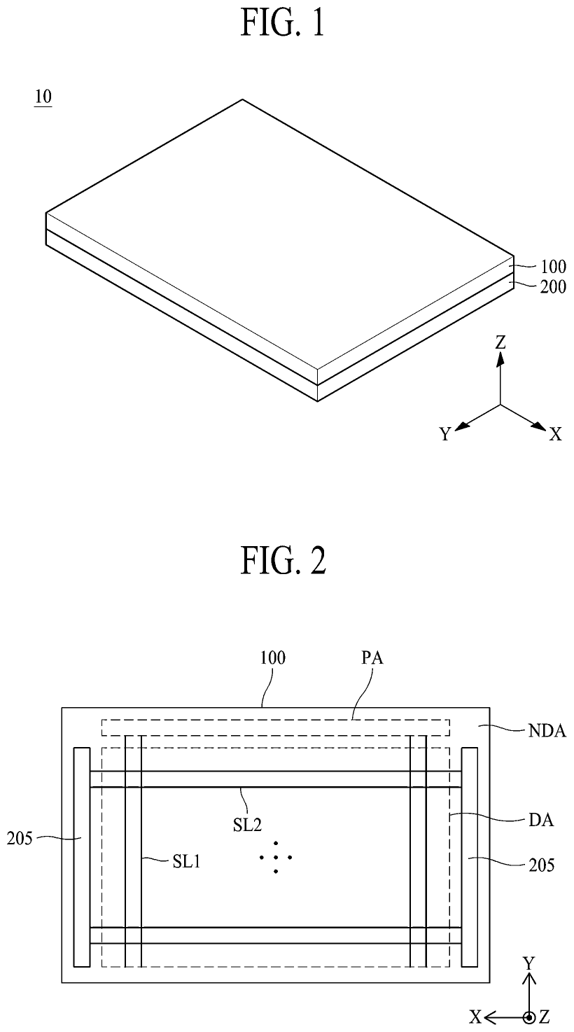

In FIGS. 1 and 2, an X axis represents a direction parallel to a gate line, a Y axis represents a direction parallel to a data line, and a Z axis represents a height direction of the display device.

Although a transparent display device 10 according to one or more example embodiments of the present disclosure is described as an organic light emitting display apparatus (OLED), the transparent display device 10 can be implemented as a liquid crystal display (LCD) apparatus, a quantum dot light emitting display (QLED) apparatus, or an electrophoretic display apparatus and is not limited thereto.

Referring to FIG. 1, the transparent display device 10 according to one or more example embodiments of the present disclosure includes a transparent display panel 100 and a light controlling panel 200.

The transparent display panel 100 is provided with a plurality of pixels to display images. The transparent display panel 100 can include a transmissive area in at least some areas. The transmissive area can allow most of the light incident from the outside to pass through. The transmissive area can be disposed between a plurality of pixels. The transparent display panel 100 allows external objects or background scenes to be visible due to the transmissive area.

The light controlling panel 200 can be disposed on at least one side of the transparent display panel 100 and can control light incident on the transparent display panel 100. The light controlling panel 200 can include an electrophoretic element that moves by an electric field. The light controlling panel 200 can control the movement of the electrophoretic element to implement a light-blocking mode and a light-transmitting mode. The electrophoretic element can switch from the light-blocking mode to the light-transmitting mode or from the light-transmitting mode to the light-blocking mode depending on whether a voltage is applied. The light controlling panel 200 can block incident light in the light-blocking mode and transmit incident light in the light-transmitting mode.

The light controlling panel 200 can be preferably disposed in a direction opposite to the direction in which the transparent display panel 100 emits light. For example, as shown in FIG. 1, when the transparent display panel 100 is a top emission type, the light controlling panel 200 can be disposed below the transparent display panel 100. For another example, when the transparent display panel 100 is a bottom emission type, the light controlling panel 200 can be disposed over the transparent display panel 100.

The light controlling panel 200 can be adhered to one surface of the transparent display panel 100 using an adhesive layer. The adhesive layer can be a transparent adhesive film such as optically clear adhesive OCA or a transparent adhesive such as optically clear resin OCR.

In FIG. 1, it is illustrated that the light controlling panel 200 is disposed on one surface exposed to the outside of the transparent display panel 100, but it is not necessarily limited thereto. The light controlling panel 200 can be disposed within the transparent display panel 100. In this case, the light controlling panel 200 can be disposed on the top surface of any one of the plurality of layers provided in the transparent display panel 100. As an example, the light controlling panel 200 can be disposed between the substrate and the transistor of the transparent display panel 100. For this example, the light controlling panel 200 cannot include a separate substrate.

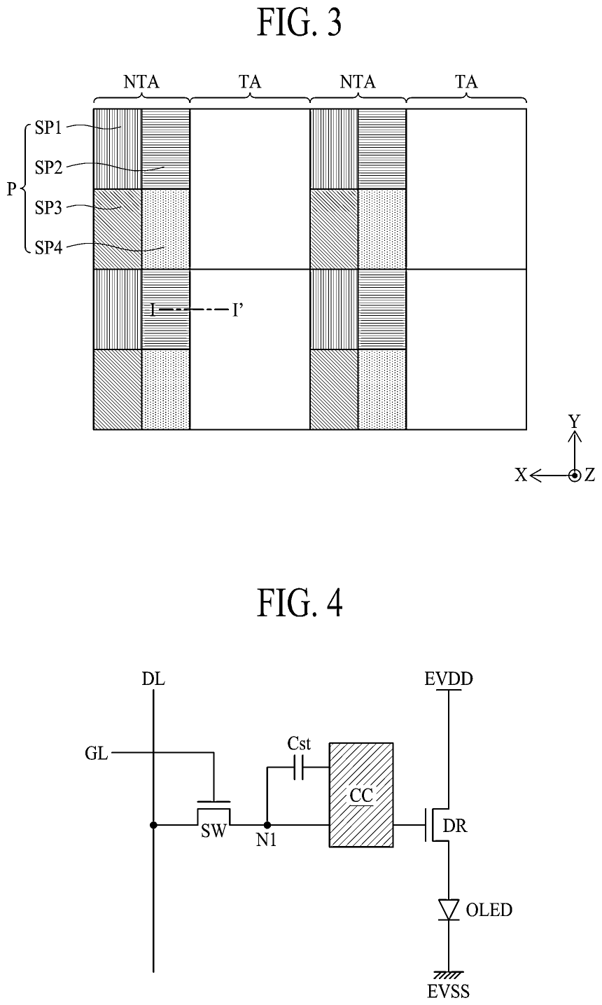

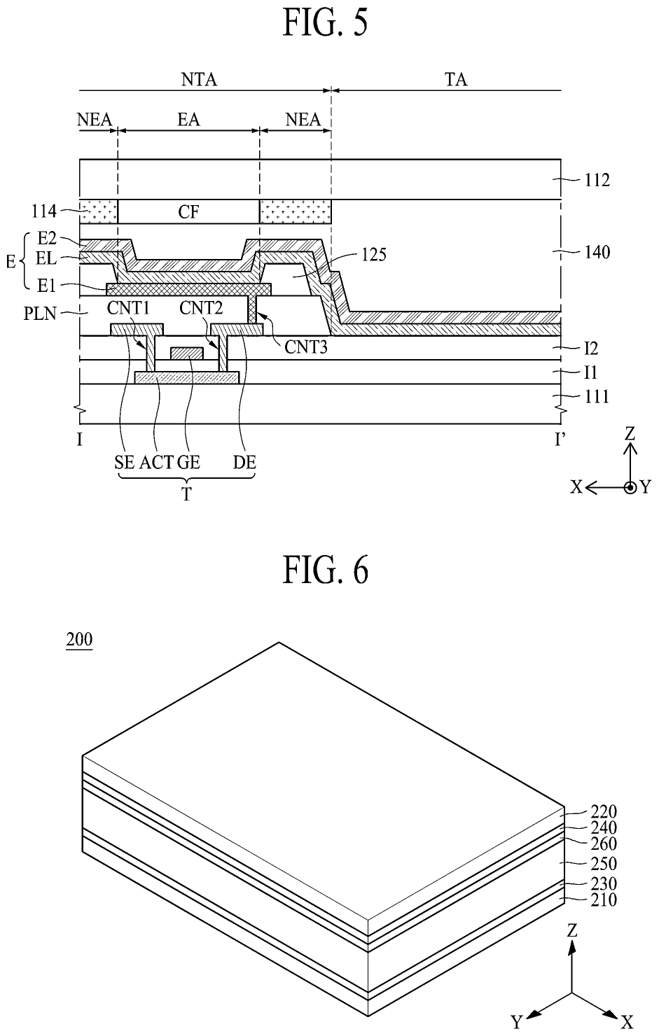

Hereinafter, the transparent display panel 100 will be described in more detail with reference to FIGS. 2 to 5. FIG. 2 is a plan view illustrating a transparent display panel according to one or more example embodiments of the present disclosure, FIG. 3 is a diagram illustrating an example of a transmissive area and a non-transmissive area provided in the display area of FIG. 2, FIG. 4 is an example of a circuit diagram of a sub-pixel illustrated in FIG. 3, and FIG. 5 is an example of a cross-sectional view illustrating an example of I-I′ of FIG. 3.

Referring to FIGS. 2 to 5, the transparent display panel 100 according to one or more example embodiments of the present disclosure can include a display area DA and a non-display DA. The display area DA includes pixels P to display images, the non-display area NDA does not display images.

The display area DA can include first signal lines SL1, second signal lines SL2, and pixels. The non-display area NDA can include a pad area PA in which pads are arranged and at least one scan driver 205.

The first signal lines SL1 can extend in a first direction (e.g., Y-axis direction) in the display area DA. For example, the first signal lines SL1 can be data lines, but are not necessarily limited thereto. The first signal lines SL1 can include at least one of a pixel power line, a common power line, and a reference line.

The second signal lines SL2 can extend in a second direction (e.g., X-axis direction) in the display area DA. The second signal lines SL2 can intersect the first signal lines SL1 in the display area DA. For example, the second signal lines SL2 can be scan lines, but are not necessarily limited thereto.

The scan driver 205 is connected to scan lines and supplies scan signals. The scan driver 205 can be disposed in the non-display area NDA outside one side or both sides of the display area DA of the transparent display panel 100. The scan driver 205 can be formed using a gate driver in panel GIP method or a tape automated bonding TAB method.

As shown in FIG. 3, the display area DA includes a transmissive area TA and a non-transmissive area NTA. The transmissive area TA is an area that transmits most of the light incident from the outside. The non-transmissive area NTA is an area that does not transmit most of the light incident from the outside. For example, the transmissive area TA can have a light transmittance greater than a %, and the non-transmissive area NTA can have a light transmittance less than R %. In this example, a is greater than 3, and each of a and R can be a positive number. The transparent display device 10 can allow viewing of an object or background scenes that are located at a rear surface of the transparent display device 10 due to the transmissive area TA of the transparent display panel 100.

The non-transmissive area NTA includes an emission area EA in which a plurality of pixels P are provided to emit light. Each of the plurality of pixels P can include a first sub-pixel SP1, a second sub-pixel SP2, a third sub-pixel SP3, and a fourth sub-pixel SP4. The first sub-pixel SP1 can include a first emission area EA that emits light of a first color, and the second sub-pixel SP2 can include a second emission area EA that emits light of a second color. The third sub-pixel SP3 can include a third emission area EA that emits third color light, and the fourth sub-pixel SP4 can include a fourth emission area EA that emits fourth color light.

For example, the first to fourth emission areas EA can emit light of different colors. For example, the first emission area EA can emit green light, and the second emission area EA can emit red light. The third emission area EA can emit blue light, and the fourth emission area EA can emit white light. However, it is not necessarily limited thereto. Additionally, the arrangement order of each sub-pixels SP1, SP2, SP3, and SP4 can be changed in various ways.

Referring to FIG. 4, each of the sub-pixels SP1, SP2, SP3, and SP4 can include a switching transistor SW, a driving transistor DR, a capacitor Cst, a compensation circuit CC, and an organic light emitting diode OLED.

The switching transistor SW supplies a data signal supplied via the data line DL to the first node N1 in response to a scan signal supplied via the gate line GL. The capacitor Cst is electrically connected to the first node N1 to charge the voltage applied to the first node N1. The driving transistor DR can control the amount of driving current flowing to the organic light emitting diode OLED in response to a voltage applied to a gate electrode.

A semiconductor layer of the switching transistor SW and/or the driving transistor DR can include, but is not limited thereto, silicon, such as a-Si, poly-Si, or low-temperature poly-Si, or can include an oxide, such as indium-gallium-zinc-oxide IGZO.

The organic light emitting diode OLED outputs light corresponding to the driving current. The organic light emitting diode OLED can output light corresponding to any one of the red color, the green color, and the blue color. The organic light emitting diode OLED can include an anode electrode, a light emitting layer formed on the anode electrode, and a cathode electrode which applies common voltage. The light emitting layer can be implemented to emit the same color of light per pixel, such as white light, or can be implemented to emit different colors of light per pixel, such as red light, green light, or blue light.

The compensation circuit CC can be disposed in the pixel to compensate for a threshold voltage of the driving transistor DR. The compensation circuit CC can include one or more transistors. The compensation circuit CC can include one or more transistors and capacitors and can be configured in various ways depending on the compensation method. The pixel including the compensation circuit CC can have various structures, such as 3T1C, 4T2C, 5T2C, 6T1C, 6T2C, 7T1C, 7T2C, etc.

Referring to FIG. 5, the transparent display panel 100 according to one or more example embodiments of the present disclosure includes a lower substrate 111 and a upper substrate 112 facing each other. A transistor T and a light emitting device E can be disposed between the lower substrate 111 and the upper substrate 112. The light emitting device E can include a lower electrode E1, an organic layer EL, and an upper electrode E2.

The transistor T can include an active layer ACT disposed on the lower substrate 111, a first insulating film I1 disposed on the active layer ACT, a gate electrode GE disposed on the first insulating film I1, a second insulating film I2 disposed on the gate electrode GE, a source electrode SE, and a drain electrode DE. The source electrode SE and the drain electrode DE are disposed on the second insulating film I2 and connected to the active layer ACT through the first and second contact holes CNT1 and CNT2. In FIG. 5, it is illustrated that the transistor T is a top gate type, but it is not necessarily limited thereto, the transistor T can be a bottom gate type in which the gate electrode GE is disposed below the active layer ACT.

The planarization film PLN can be disposed on the transistor T to planarize a step difference due to the transistor T and a plurality of signal lines. The planarization film PLN is disposed in the non-transmissive area NTA and cannot be disposed in at least a portion of the transmissive area TA. The planarization film PLN can cause refraction of light as it passes through, thereby impairing transparency. Accordingly, the transparent display panel 100 according to an example embodiment of the present disclosure can increase transparency by removing a portion of the planarization film PLN from the transmissive area TA.

Meanwhile, in FIG. 5, it is illustrated that the first and second insulating films I1 and I2 disposed below the planarization film PLN are provided not only in the non-transmissive area NTA but also in the transmissive area TA, but are not necessarily limited thereto. In another example embodiment, some of the insulating films disposed below the planarization film PLN cannot be provided in at least a portion of the transmissive area TA in order to increase transparency. For example, the second insulating film I2 can be provided in the non-transmissive area NTA and cannot be provided in at least a portion of the transmissive area TA.

A bank 125 and the light emitting device E including the lower electrode E1, the organic layer EL, and the upper electrode E2 can be disposed on the planarization film PLN.

The lower electrode E1 can be disposed for each sub-pixels SP1, SP2, SP3, and SP4 on the planarization film PLN, and cannot be disposed in the transmissive area TA. The lower electrode E1 can be electrically connected to the transistor T. Specifically, the lower electrode E1 can be connected to one of the source electrode SE and the drain electrode DE of the transistor T through the third contact hole CNT3 penetrating the planarization film PLN. A bank 125 is disposed between adjacent lower electrodes E1, so that the adjacent lower electrodes E1 can be electrically insulated from each other.

The lower electrode E1 can include a highly reflective metal material, such as a stacked structure of aluminum and titanium (Ti/Al/Ti), a stacked structure of aluminum and ITO (ITO/Al/ITO), Ag alloy, a stacked structure of Ag alloy and ITO (ITO/Ag alloy), MoTi alloy, and/or a stacked structure of MoTi alloy and ITO (ITO/MoTi alloy/ITO). The Ag alloy can be an alloy of silver Ag, palladium Pd, and copper Cu. MoTi alloy can be an alloy of molybdenum Mo and titanium Ti. The lower electrode E1 can be an anode electrode.

The bank 125 can be disposed on the planarization film PLN. Additionally, the bank 125 can be disposed to cover an edge of the lower electrode E1 and expose a portion of the lower electrode E1. Accordingly, the bank 125 can reduce or prevent the problem of reducing emission efficiency due to concentration of a current on an end of the lower electrode EL.

The organic layer EL can be dispose on the lower electrode E1. The organic layer EL can include a hole transporting layer, a light emitting layer, and an electron transporting layer. In this case, when the voltage is applied to the lower electrode E1 and the upper electrode E2, holes and electrons move to the light emitting layer through the hole transport layer and electron transport layer, respectively, and combine with each other in the light emitting layer to emit light. In one example embodiment, the organic layer EL can be a common layer commonly formed in the sub-pixels SP1, SP2, SP3, and SP4. In this example, the light emitting layer can be a white light emitting layer that emits white light. In another example embodiment, the light emitting layer of the organic layer EL cannot be formed in the transmissive area TA.

The upper electrode E2 can be provided on the organic layer EL and the bank 125. The upper electrode E2 can be made of a transparent metal material (TCO, Transparent Conductive Material) such as ITO or IZO that can transmit light, or can be formed of a semi-transmissive conductive material such as magnesium Mg, silver Ag, or an alloy of magnesium Mg and silver Ag. When the upper electrode E2 is formed of the semi-transmissive conductive material, light emission efficiency can be increased due to a micro cavity. The upper electrode E2 can be a cathode electrode.

An encapsulation film 140 can be disposed on the light emitting element E. The encapsulation film 140 can be formed on the upper electrode E2 to cover the upper electrode E2. The encapsulation film 140 serves to reduce or prevent oxygen or moisture from penetrating into the organic layer EL and the upper electrode E2. To this end, the encapsulation film 140 can include at least one inorganic film and at least one organic film.

A color filter CF can be disposed on one side of the upper substrate 112 facing the lower substrate 111. The color filter CF can be patterned for each sub-pixel SP1, SP2, SP3, and SP4.

Specifically, the color filter CF can include a first color filter, a second color filter, a third color filter, and a fourth color filter. The first color filter can be arranged to correspond to the emission area EA of the first sub-pixel SP1. For example, the first color filter can be a green color filter that transmits green light. The second color filter can be arranged to correspond to the emission area EA of the second sub-pixel SP2 and can be a red color filter that transmits red light. The third color filter CF3 can be arranged to correspond to the emission area EA of the third sub-pixel SP3 and can be a blue color filter that transmits blue light. The fourth color filter can be arranged to correspond to the emission area EA4 of the fourth sub-pixel SP4 and can be a white color filter that transmits white light. The white color filter can be made of a transparent organic material that transmits white light, but it is not necessarily limited thereto.

A light blocking layer 114 can be disposed between the color filters CF. The light blocking layer 114 is disposed between the sub-pixels SP1, SP2, SP3, and SP4 to reduce or prevent color mixing between adjacent sub-pixels SP1, SP2, SP3, and SP4. Additionally, the light blocking layer 114 can reduce or prevent light incident from the outside from being reflected on a plurality of signal lines disposed between the sub-pixels SP1, SP2, SP3, and SP4.

In addition, the light blocking layer 114 is disposed between the transmissive area TA and the plurality of sub-pixels SP1, SP2, SP3, and SP4 to reduce or prevent light emitted from each of the plurality of sub-pixels SP1, SP2, SP3, and SP4 from proceeding to the transmission area TA. In one example embodiment, the light blocking layer 114 cannot be disposed between the white sub-pixel and the transmissive area TA. The display panel 110 according to an example embodiment of the present disclosure does not include the light blocking layer 114 between the white sub-pixel and the transmissive area TA, thereby reducing the area where the light blocking layer 114 is formed. Through this, the display panel 110 according to an example embodiment of the present disclosure can improve transmittance. The light blocking layer 114 can include a material that absorbs light, for example, a black dye that absorbs all light in the visible light wavelength range. The light blocking layer 114 can be a block matrix BM.

The color filter CF and the light blocking layer 114 described above are not disposed in the transmissive area TA in order to maintain high light transmittance in the transmissive area TA.

The lower substrate 111 may be a plastic film, a glass substrate, or a silicon wafer substrate formed using a semiconductor process. The upper substrate 112 may be a plastic film, a glass substrate, or an encapsulation film. The lower substrate 111 and upper substrate 112 may be made of a transparent material. The lower substrate 111 may be formed to be larger than the upper substrate 112, and as a result, a portion of the lower substrate 111 may be exposed without being covered by the upper substrate 112.

As described above, the transparent display device 10 according to an example embodiment of the present disclosure includes the transmissive area TA that allows most of the light incident from the outside to pass through and the emission area EA that emits light. As a result, in the example embodiment of the present disclosure, an object or background scenes located on the rear surface or the front surface of the transparent display device 10 can be viewed through the transmissive areas TA of the transparent display device 10.

FIG. 6 is a perspective view illustrating a light controlling panel according to one or more example embodiments of the present disclosure.

Referring to FIG. 6 to 12B, the light controlling panel 200 according to an example embodiment of the present disclosure can be implemented to operate in the light-transmitting mode that transmits incident light and the light-blocking mode that blocks incident light. In an example embodiment of the present disclosure, it can be assumed that the light-blocking mode is a case where the light transmittance of the light controlling panel 200 is less than a %, and the light-transmitting mode is a case where the light transmittance of the light controlling panel 200 is equal to or greater than a %. In this example, a can be less than a, and each of a and a can be a positive number. The light transmittance of the light controlling panel 200 represents the ratio of light output to light incident on the light controlling panel 200.

To this end, as shown in FIG. 6, the light controlling panel 200 according to an example embodiment of the present disclosure includes a first substrate 210, a first electrode 230 on the first substrate 210, a second substrate 220 facing the first substrate, a second electrode 240 on the first substrate 210, and a dielectric layer 250 between the first electrode 230 and the second electrode 240. The light controlling panel 200 can further include an adhesive layer 260 between the dielectric layer 250 and the second electrode 240.

Each of the first and second substrates 210 and 220 can be a glass substrate or a plastic film. When each of the first and second substrates 210 and 220 is a plastic film, cellulose resin such as triacetyl cellulose TAC or diacetyl cellulose DAC, etc., cyclo olefin polymer COP such as norbornene derivatives, etc., acrylic resin such as cyclo olefin copolymer COC or poly methylmethacrylate PMMA, etc., polyolefin such as polycarbonate PC, polyethylene PE, or polypropylene PP, etc., polyester such as polyvinyl alcohol PVA, poly ether sulfone PES, polyetheretherketone PEEK, polyetherimide PEI, polyethylenenaphthalate PEN, or polyethyleneterephthalate PET, etc., a sheet or film containing polyimide PI, polysulfone PSF, or fluoride resin, etc. can be used, but it is not necessarily limited thereto.

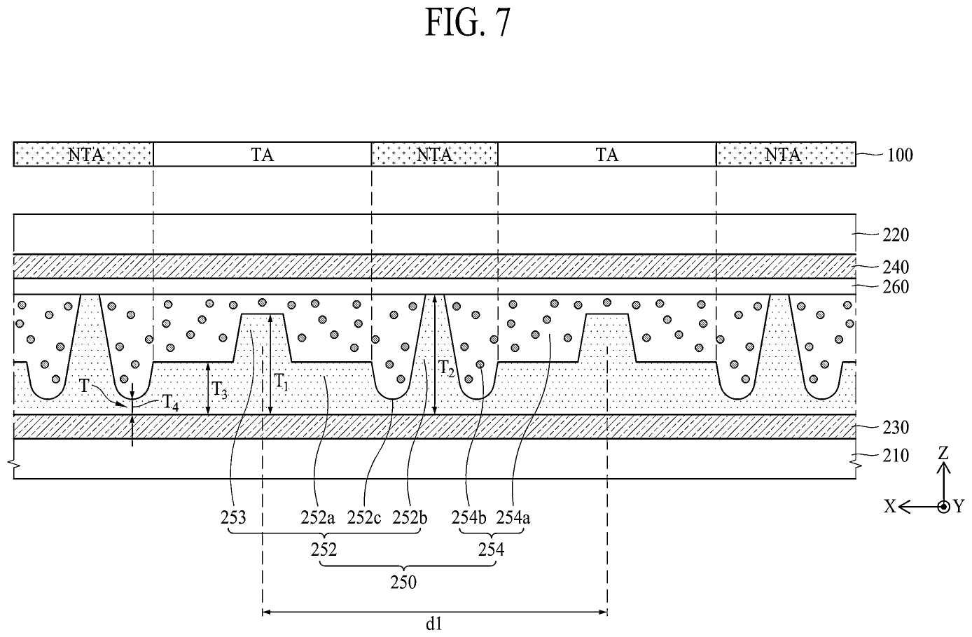

As shown in FIGS. 1 and 7, the light controlling panel 200 is disposed outside the transparent display panel 100 and can be provided in a separate configuration from the transparent display panel 100. In this case, the light controlling panel 200 can be formed in film type to disposed on one side of the transparent display panel 100 using a separate adhesive layer, but it is not necessarily limited thereto.

In another example embodiment, the light controlling panel 200 can be disposed within the transparent display panel 100. The light controlling panel 200 can be disposed between the lower substrate 111 and the upper substrate 112 of the transparent display panel 100. In this case, the first substrate 210 and the second substrate 220 can be omitted in the light controlling panel 200.

The first electrode 230 can be disposed on one side of the first substrate 210 facing the second substrate 220. The second electrode 240 can be disposed on one side of the second substrate 220 facing the first substrate 210. Each of the first electrode 230 and the second electrode 240 can be formed as an integral electrode that overlaps the entire display area DA of the transparent display panel 100. In contrast, when each of the first electrode 230 and the second electrode 240 is formed with a plurality of pattern electrodes, expensive pattern electrode processing costs are incurred, and light blocking particles can be aggregated as an electric field is concentrated at both ends of the pattern electrode. Additionally, since a plurality of pattern electrodes must be controlled individually, the driving circuit is complicated.

Since the light controlling panel 200 according to an example embodiment of the present disclosure includes each of the first electrode 230 and the second electrode 240 formed as one integral electrode, it is not necessary to process into a plurality of electrode patterns, thereby reducing electrode processing cost. Furthermore, it is not necessary to control individually each of the plurality of electrode patterns, thereby simplifying the driving circuit. In addition, since the first electrode 230 and second electrode 240 are formed as one integral electrode without patterning in an area overlapping the display area DA of the transparent display panel 100, a clump of the light blocking particles by the electric field concentrated in both ends of the electrode pattern can be reduced or prevented.

Each of the first electrode 230 and the second electrode 240 can be transparent electrode. Each of the first electrode 230 and the second electrode 240 can include silver oxide (e.g. AgO or Ag2O or Ag2O3), aluminum oxide (e.g. Al2O3), tungsten oxide (e.g. WO2 or WO3 or W2O3), magnesium oxide (e.g. MgO), molybdenum oxide (e.g. MoO3), zinc oxide (e.g. ZnO), tin oxide (e.g. SnO2), indium oxide (e.g. In2O3), chromium oxide (e.g. CrO3 or Cr2O3), antimony oxide (e.g. Sb2O3 or Sb2O5), titanium oxide (e.g. TiO2), nickel oxide (e.g. NiO), copper oxide (e.g. CuO or Cu2O), vanadium oxide (e.g. V2O3 or V2O5), cobalt oxide (e.g. CoO), iron oxide (e.g. Fe2O3 or Fe3O4), niobium oxide (e.g. Nb2O5), indium tin oxide (e.g. Indium Tin Oxide, ITO), indium zinc oxide (e.g. Indium Zinc Oxide, IZO), aluminum doped zinc oxide (e.g. ZAO), aluminum doped tin oxide (e.g. TAO), or antimony tin oxide (e.g. ATO), but it is not necessarily limited thereto.

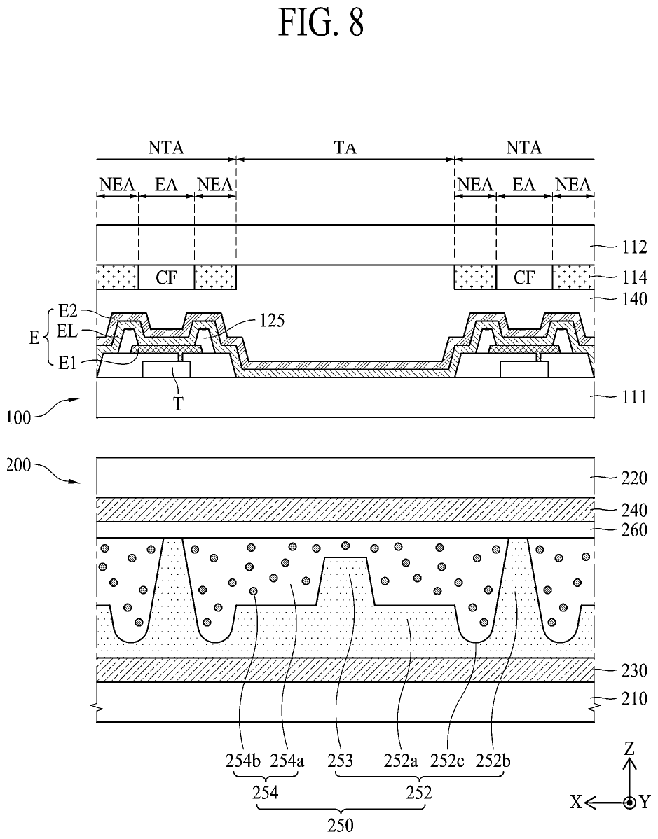

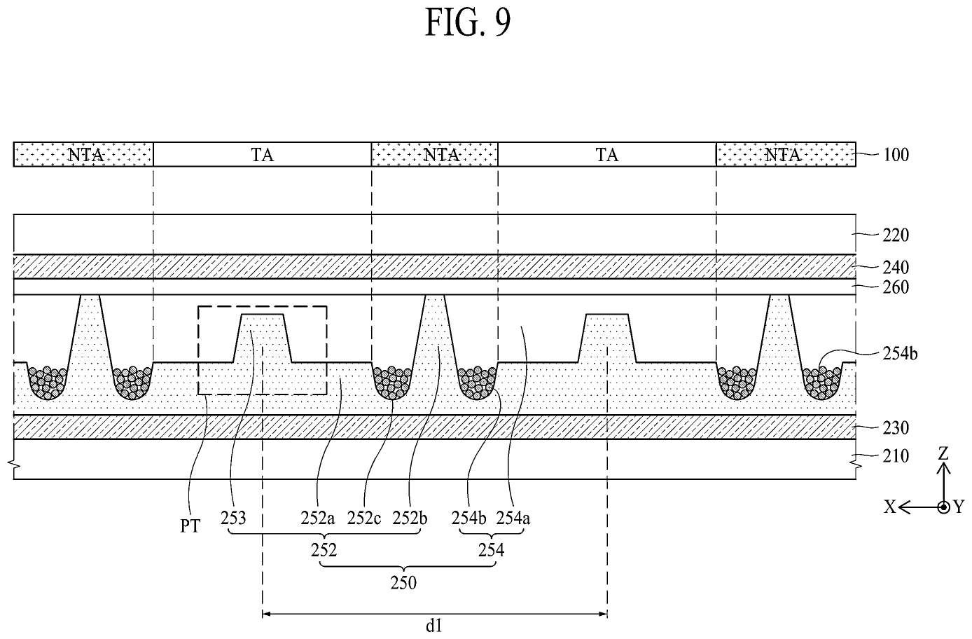

As shown FIGS. 7 to 9, the dielectric layer 250 is disposed between the first electrode 230 and the second electrode 240 to implement a light-blocking mode or a light-transmitting mode depending on whether a voltage is applied to the first electrode 230 and the second electrode 240. For example, the dielectric layer 250 can implement the light-transmitting mode (See FIG. 9) when the voltage is applied to the first electrode 230 and the second electrode 240. On the other hand, the dielectric layer 250 can implement the light-blocking mode (See FIGS. 7 and 8) when no voltage is applied to the first electrode 230 and the second electrode 240.

The dielectric layer 250 can include a first dielectric 252 and a second dielectric 254. The first dielectric 252 and the second dielectric 254 can be made of different dielectric materials. The light controlling panel 200 according to an example embodiment of the present disclosure can control the direction of the electric field in a desired direction by utilizing the shape of the interface between the first dielectric 252 and the second dielectric 254 and the difference in dielectric permittivity between the first dielectric 252 and the second dielectric 254.

Specifically, the first dielectric 252 is disposed on one side of the first electrode 230 facing the second electrode 240. The first dielectric 252 can be made of a first dielectric material having a first dielectric permittivity. The first dielectric 252 can include a first dielectric pattern 252a, a spacer 252b, a groove 252c, and a protrusion 253 on the first dielectric pattern 252a.

The first dielectric pattern 252a can guide the plurality of light blocking particles 254b included in the second dielectric 254 to the groove 252c disposed between the first dielectric patterns 252a. Specifically, the protrusion 253 can be disposed on the top surface of the first dielectric pattern 252a. The protrusion 253 can be a portion of the top surface of the first dielectric pattern 252a that protrudes toward the second electrode 240. In this example, the top surface of the first dielectric pattern 252a adjacent to the protrusion 253 can be flat. The protrusion 253 can be disposed at a center of the top surface of the first dielectric pattern 252a.

In this case, when the voltage is applied to the first electrode 230 and the second electrode 240, dielectric polarization occurs in the first dielectric material of the first dielectric pattern 252a, and the dielectric polarization density can vary depending on the shape of the top surface of the first dielectric pattern 252a. Accordingly, the electric field can be generated in a direction inclined toward the groove 252c due to the protrusion 253 of the first dielectric pattern 252a.

The plurality of light blocking particles 254b included in the second dielectric 254 can move by the electric field generated between the first electrode 230 and the second electrode 240. When the voltage is applied to the first electrode 230 and the second electrode 240, the plurality of light blocking particles 254b can move to the groove 252c along the direction of the electric field as shown in FIG. 9. Accordingly, when the voltage is applied to the first electrode 230 and the second electrode 240, the plurality of light blocking particles 254b cannot be disposed on (or above) the area where the first dielectric pattern 252a is disposed, and the area where the first dielectric pattern 252a is disposed can have high light transmittance. Accordingly, when the voltage is applied to the first electrode 230 and the second electrode 240, external light can be transmitted through the area where the first dielectric pattern 252a is disposed, and thus, the light passing through the light controlling panel 200 can be incident on the transparent display panel 100.

A distance between a center of one first dielectric pattern 252a and a center of the adjacent other first dielectric pattern 252a can be a first distance d1. The first distance d1 can be equal to the distance from the center of one protrusion 253 to the center of the adjacent other protrusion 253.

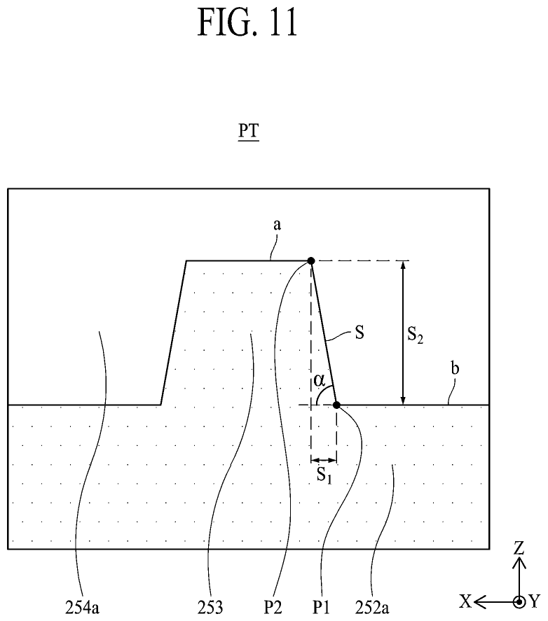

Referring to FIG. 11, the protrusion 253 on the first dielectric pattern 252a can be protruded from the flat top surface (b) of the first dielectric pattern 252a toward the second electrode 240 to have a predetermined thickness or predetermined height S₂. The side surface (S) of the protrusion 253 can be inclined at a predetermined angle α from the flat top surface (b) of the first dielectric pattern 252a. The top surface (a) of the protrusion 253 can be flat. The side surface (S) of the protrusion 253 can have a regular tapered shape.

In this case, a horizontal distance Si between a first point P1 and a second point P2 can be less than a vertical distance S₂ which is a height of the protrusion 253. The first point P1 is a point where the top surface (b) of the first dielectric pattern 252a and one end of the side surface (S) of the protrusion 253 meet. The second point P2 is a point where the top surface (a) of the protrusion 253 and the other end of the side surface (S) of the protrusion 253 meet. When the horizontal distance S₁ of the protrusion 253 is smaller than the vertical distance S₂ of the protrusion 253, the proportion of light emitted through the first dielectric pattern 252a and the protrusion 253 can be increased, thereby reducing or preventing image quality distortion from degrading.

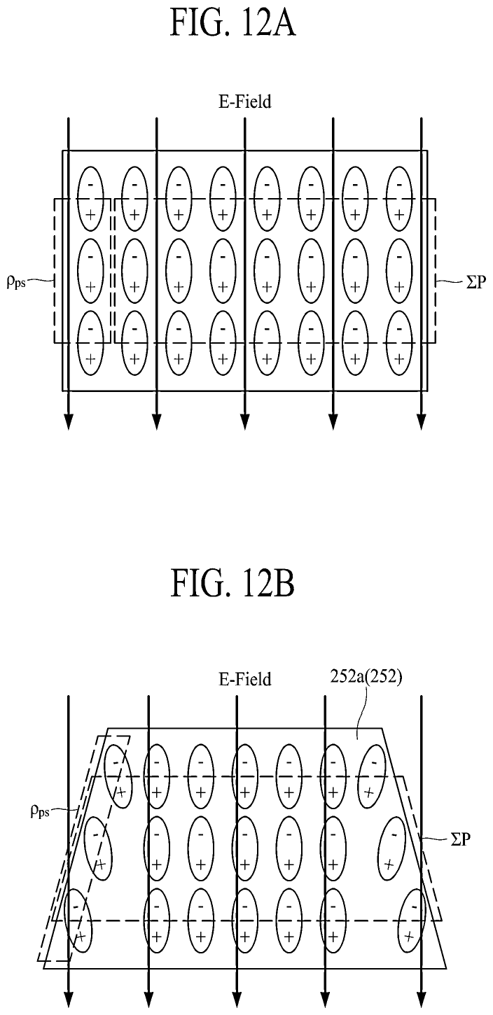

The angle α of the side surface (S) of the protrusion 253 can be greater than 45 degrees and less than 90 degrees. Here, the angle α is an inner angle of the protrusion 253 formed by the top surface (b) of the first dielectric pattern 252a and the side surface (S) of the protrusion 253. As in the experimental example shown in FIG. 12A, when the angle α of the protrusion 253 is 90 degrees, since the surface polarization density ρₚₛ becomes zero, the charge amount influence can be reduced and thus the driving characteristic can be deteriorated. However, as shown in FIG. 12B, in an example embodiment of the present disclosure, when the angle α of the protrusion 253 is an acute angle or less than 90 degrees, since the surface polarization density ρₚₛ becomes greater than zero, the charge amount can be increased and thus the driving characteristic can be improved.

Since the first dielectric pattern 252a according to one or more example embodiments of the present disclosure can have the protrusion 253 on a portion of the top surface of the first dielectric pattern 252a, and the protrusion 253 can have an inclined side surface, a change can occur in the surface polarization density or the dielectric polarization density when the voltage is applied to the first electrode 230 and the second electrode 240. In this case, the electric field may be generated in a direction perpendicular to the first electrode 230 and in a direction inclined to the first electrode 230 around the protrusion 253. The plurality of light blocking particles 254b included in the second dielectric 254 are moved in the direction perpendicular to the first electrode 230 and in the direction inclined to the first electrode 230 when the voltage is applied to the first electrode 230 and the second electrode 240.

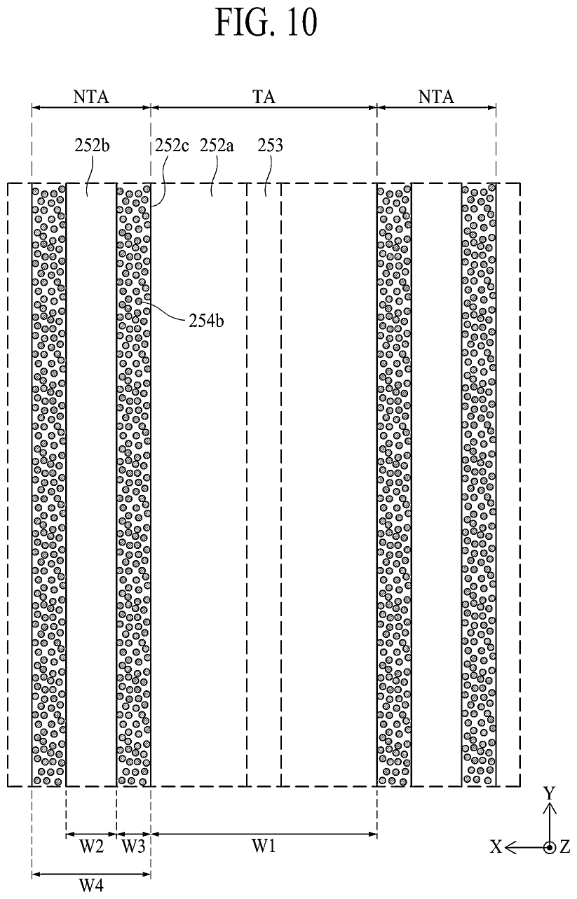

Accordingly, the plurality of light blocking particles 254b move into the groove 252c in the area where the groove 252c is formed as shown in FIGS. 9 and 10, and some of the plurality of light blocking particles 254b distributed on the top surface of the first dielectric pattern 252a also move into the groove 252c along the inclined direction.

Thus, since the protrusion 253 with an inclined side surface can be disposed on the portion of the top surface of the first dielectric pattern 252a, the light controlling panel 200 according to one or more example embodiments of the present disclosure can control the direction of the electric field to be directed toward the groove 252c when the voltage is applied to the first electrode 230 and the second electrode 240. Accordingly, the light control panel 200 according to one example embodiment of the present disclosure can significantly increase the light transmittance in the light-transmitting mode because the plurality of light blocking particles 254b can move into the groove 252c instead of being distributed in areas other than the groove 252c.

Furthermore, in the light controlling panel 200 according to one example embodiment of the present disclosure, since a portion of the top surface of the first dielectric pattern 252a can be flat, and the top surface of the protrusion 253 can be flat, when the light is transmitted in the light-transmitting mode, the light can be reduced or prevented from being significantly refracted on the top surface of the first dielectric pattern 252a and the protrusion 253.

Additionally, in the light controlling panel 200 according to an example embodiment of the present disclosure, the portion of the top surface of the first dielectric pattern 252a can be flat and the top surface of the protrusion 253 can be flat, thereby reducing or preventing the double image from occurring.

The first dielectric pattern 252a can be disposed to overlap the transmissive area TA of the transparent display panel 100 as shown in FIG. 8. In the light controlling panel 200 according to an example embodiment of the present disclosure, in the light-transmitting mode, the plurality of light blocking particles 254b can move into the groove 252c and cannot remain in the area where the first dielectric pattern 252a is disposed. In the light controlling panel 200 according to an example embodiment of the present disclosure, external light can be transmitted through an area where the plurality of light blocking particles 254b are not disposed, that is, the area where the first dielectric pattern 252a is disposed. The light passing through the light controlling panel 200 is incident on the transparent display panel 100 and can pass through the transparent display panel 100 through the transmissive area TA of the transparent display panel 100.

In this way, external light can penetrate the transparent display device 10 through the area where the first dielectric pattern 252a of the light controlling panel 200 is disposed and the transmissive area TA of the transparent display panel 100. In the transparent display device 10 according to an example embodiment of the present disclosure, the first dielectric pattern 252a of the light controlling panel 200 can be disposed to overlap with the transmissive area TA of the transparent display panel 100 in order to achieve high light transmittance in the light-transmitting mode.

The first dielectric pattern 252a of the light controlling panel 200 can be disposed not to overlap the non-transmissive area NTA of the transparent display panel 100. That is, the first dielectric pattern 252a of the light controlling panel 200 can be disposed not to overlap the light emitting device E of the transparent display panel 100. Additionally, the first dielectric pattern 252a of the light controlling panel 200 can be disposed not to overlap the transistor T of the transparent display panel 100. Additionally, the first dielectric pattern 252a of the light controlling panel 200 can be disposed not to overlap the color filter CF and the light blocking layer 114 of the transparent display panel 100.

The one first electrode 230 or the one second electrode 240 can be disposed to overlap with a plurality of first dielectric patterns 252a. The one first electrode 230 or the one second electrode 240 can be disposed to overlap with a plurality of spacers 252b. The one first electrode 230 or the one second electrode 240 can be disposed to overlap with a plurality of grooves 252c. The one first electrode 230 or the one second electrode 240 can be disposed to correspond to a plurality of protrusions 253. For example, the one first electrode 230 or the one second electrode 240 can be disposed to overlap with the plurality of protrusions 253.

The first dielectric pattern 252a can be extended in one direction. In one example embodiment, the first dielectric pattern 252a can be extended in a first direction (e.g., Y-axis direction) as shown in FIG. 10. For example, The first dielectric pattern 252a can be extended parallel to the first signal lines SL1. The first dielectric pattern 252a is disposed to overlap the transmissive area TA of the transparent display panel 100 and can have a first width W1. The first width W1 can be equal to or greater than the width in the first direction (e.g., Y-axis direction) of the transmissive area TA of the transparent display panel 100. In this case, the light controlling panel 200 according to an example embodiment of the present disclosure can include only one first dielectric pattern 252a between two adjacent spacers 252b.

In FIG. 10, it is illustrated that the first dielectric pattern 252a is extended in a first direction (e.g., Y-axis direction), but it is not necessarily limited thereto. The extension direction of the first dielectric pattern 252a can vary depending on the shape of the transmissive area TA in the transparent display panel 100. As shown in FIG. 3, the transparent display panel 100 can include the transmissive areas TA disposed in a line along the first direction (e.g., Y-axis direction). In this case, the first dielectric pattern 252a can be extended in the first direction (e.g., Y-axis direction) as shown in FIG. 10.

However, unlike the configuration shown in FIG. 3, the transparent display panel 100 can include the transmissive areas TA disposed in a line along a second direction (e.g., X-axis direction). In this case, the first dielectric pattern 252a can be extended in the second direction (e.g., X-axis direction).

The spacer 252b can be disposed between the first electrode 230 and the second electrode 240 to maintain the gap between the first electrode 230 and the second electrode 240. The spacer 252b can be disposed between first dielectric patterns 252a arranged adjacently on a plane. The groove 252c can be disposed at (or on) at least one side of the spacer 252b.

The spacer 252b can be spaced apart from the first dielectric pattern 252a with the groove 252c interposed therebetween. For example, the spacer 252b can be disposed between two first dielectric patterns 252a. One groove 252c can be disposed on one side of the spacer 252b facing one first dielectric pattern 252a, and the spacer 252b can be spaced apart from the one first dielectric pattern 252a with the one groove 252c interposed therebetween. In addition, another groove 252c can be disposed on the other side of the spacer 252b facing the other first dielectric pattern 252a, and the spacer 252b can be spaced apart from the other first dielectric pattern 252a with the other groove 252c interposed therebetween. The spacer 252b can be disposed between the two grooves 252c.

The spacer 252b can be disposed to overlap the non-transmissive area NTA of the transparent display panel 100. The spacer 252b can be extended in one direction in an area overlapping the non-transmissive area NTA of the transparent display panel 100. In one example embodiment, the spacer 252b can be extended in the first direction (e.g., Y-axis direction) as shown in FIG. 10. For example, the spacer 252b can be extended parallel to the first signal lines SL. The spacer 252b can have a second width W2 and be extended in the first direction (e.g., Y-axis direction) parallel to the first dielectric pattern 252a. The second width W2 can be smaller than the first width W1 of the first dielectric pattern 252a and smaller than the width in the first direction (e.g., Y-axis direction) of the non-transmissive area NTA of the transparent display panel 100.

In FIG. 10, it is illustrated that the spacer 252b is extended in the first direction (e.g., Y-axis direction), but it is not necessarily limited thereto. The direction in which the spacer 252b is extended can vary depending on the shape of the non-transmissive area NTA in the transparent display panel 100. As shown in FIG. 3, the transparent display panel 100 can have non-transmissive area NTA disposed in a line along the first direction (e.g., Y-axis direction). In this case, the spacer 252b can be extended in the first direction (e.g., Y-axis direction) as shown in FIG. 10.

However, in the transparent display panel 100, unlike the configuration shown in FIG. 3, the non-transmissive areas NTA can be disposed in a line along the second direction (e.g., X-axis direction). In this case, the spacer 252b can be extended in the second direction (e.g., X-axis direction).

The groove 252c can be disposed between the first dielectric pattern 252a and the spacer 252b. The groove 252c can be formed concavely toward the first electrode 230 and can gather the light blocking particles 254b included in the second dielectric 254 in the light-transmitting mode.

The groove 252c can be disposed to overlap the non-transmissive area NTA of the transparent display panel 100. That is, as shown in FIG. 8, at least a portion of the groove 252c of the light controlling panel 200 can be disposed to overlap with the light emitting device E of the transparent display panel 100. Additionally, at least a portion of the groove 252c of the light controlling panel 200 can be disposed to overlap with the transistor T of the transparent display panel 100. Additionally, at least a portion of the groove 252c of the light controlling panel 200 can be disposed to overlap the color filter CF and the light blocking layer 114 of the transparent display panel 100.

When the voltage is applied to the first electrode 230 and the second electrode 240, the plurality of light blocking particles 254b can move into the groove 252c along the direction of the electric field. In this example, the area where the groove 252c is disposed can be blocked from transmitting external light by the plurality of light blocking particles 254b. For this reason, when the area where the groove 252c is disposed overlaps the transmissive area TA of the transparent display panel 100, in the light-transmitting mode, the light transmittance of the transparent display device 10 can decrease due to the plurality of light blocking particles 254b gathered in the groove 252c of the first dielectric 252 included in the light controlling panel 200. In the light controlling panel 200 according to an example embodiment of the present disclosure, the groove 252c and the spacer 252b disposed between the grooves 252c are disposed to overlap the non-transmissive area NTA of the transparent display panel 100, and thus, in the light-transmitting mode, it is possible to reduce or prevent the light transmittance from being reduced due to the light blocking particles 254b gathered in the groove 252c.

The groove 252c can be extended in one direction. In one example embodiment, the groove 252c can be extended in the first direction (e.g., Y-axis direction) as shown in FIG. 10. For example, the groove 252c can be extended parallel to the first signal lines SL1. The groove 252c can be disposed to extend parallel to at least one of the first dielectric pattern 252a, the spacer 252b, and the protrusion 253 in an area corresponding to the non-transmissive area NTA.

The groove 252c can have a third width W3 and be extended in the first direction (e.g., Y-axis direction) parallel to the first dielectric pattern 252a. The third width W3 is smaller than the first width W1 of the first dielectric pattern 252a and smaller than the width in the first direction (e.g., Y-axis direction) of the non-transmissive area NTA of the transparent display panel 100.

More specifically, a fourth width W4 where the groove 252c and the spacer 252b are disposed can be smaller than the width in the first direction (e.g., Y-axis direction) of the non-transmissive area NTA of the transparent display panel 100. For example, when two grooves 252c are adjacently disposed with the spacer 252b therebetween, the fourth width W4 which is the sum of the third width W3 of each of the two grooves 252c and the second width W2 of the spacer 252 can be smaller than the width in the first direction (e.g., Y-axis direction) of the non-transmissive area NTA of the transparent display panel 100. Through this, the light controlling panel 200 according to an example embodiment of the present disclosure can reduce or prevent the grooves 252c from overlapping with the transmissive area TA of the transparent display panel 100, and further, in the light-transmitting mode, it is possible to reduce or prevent the light transmittance of the transparent display device 10 from being reduced due to the light blocking particles 254b gathered in the groove 252c.

In FIG. 10, it is illustrated that the groove 252c is extended in the first direction (e.g., Y-axis direction), but it is not necessarily limited thereto. The extension direction of the groove 252c can vary depending on the shape of the non-transmissive area NTA in the transparent display panel 100. As shown in FIG. 3, the transparent display panel 100 can include the non-transmissive area NTA disposed in a line along the first direction (e.g., Y-axis direction). In this case, the groove 252c can be extended in the first direction (e.g., Y-axis direction) as shown in FIG. 10.

However, in the transparent display panel 100, unlike the configuration shown in FIG. 3, the non-transmissive area NTA can be disposed in a line along the second direction (e.g., X-axis direction). In this case, the groove 252c can be extended in the second direction (e.g., X-axis direction).

In one example embodiment, the first dielectric pattern 252a, the spacer 252b, the protrusion 253, and the groove 252c included in the first dielectric 252 can be formed as a single body. The first dielectric pattern 252a, the spacer 252b, the protrusion 253, and the groove 252c included in the first dielectric 252 can be made of the same first dielectric material. The first dielectric pattern 252a, the spacer 252b, the protrusion 253, and the groove 252c included in the first dielectric 252 can be formed simultaneously through an imprinting process. The light controlling panel 200 according to an example embodiment of the present disclosure simultaneously forms the first dielectric pattern 252a, the spacer 252b, the protrusion 253, and the groove 252c through the imprinting process, thereby reducing the manufacturing process cost and the manufacturing process time due to the simplicity of the manufacturing process, and further reducing the production energy. In addition, the light controlling panel 200 according to an example embodiment of the present disclosure can reduce the manufacturing process and the generation of greenhouse gases due to the manufacturing process can be reduced, thereby improving ESG (Environment/Social/Governance) qualities.

Each of the first dielectric pattern 252a, the spacer 252b, the protrusion 253, and the groove 252c can be imprinted to have different thicknesses on one surface of the first electrode 230. The sum of a thickness of the first dielectric pattern 252a and a thickness of the protrusion 253 can be a first thickness T1, and the spacer 252b can have a second thickness T2 greater than the first thickness T1. In this example, the second thickness T2 can correspond to the separation distance between the first electrode 230 and the second electrode 240. The first dielectric pattern 252a can have a third thickness T3 smaller than the second thickness T2. The first dielectric pattern 252a can have a fourth thickness T4 in an area corresponding to the groove 252c between the first dielectric pattern 252a and the spacer 252b. The fourth thickness T4 can be smaller than the third thickness T3 of The first dielectric pattern 252a, but can be greater than 0. That is, the first dielectric 252 can be formed to have a predetermined fourth thickness T4 without exposing the first electrode 230 in the area where the groove 252c is disposed.

Since the light controlling panel 200 according to an example embodiment of the present disclosure includes a first dielectric 252 having a predetermined thickness in the area where the groove 252c is formed, when a voltage is applied to the first electrode 230 and the second electrode 240, the impact applied when the light blocking particles 254b gather into the groove 252c can be alleviated, thereby reducing or preventing the light blocking particles 254b from being damaged.

The second dielectric 254 can be disposed on one side of the second electrode 240 facing the first electrode 230. As shown in FIGS. 7 to 9, the second dielectric 254 can include a solvent 254a and a plurality of light blocking particles 254b.

The solvent 254a is disposed on the first dielectric 252 and can fill the space formed by the step difference among the first dielectric pattern 252a, the spacer 252b, the protrusion 253, and the groove 252c. The solvent 254a can be made of a second dielectric material having a second dielectric permittivity. The second dielectric permittivity can be different from the first dielectric permittivity of the first dielectric material included in the first dielectric 252. In one example embodiment, the second dielectric permittivity can be smaller than the first dielectric permittivity.

Meanwhile, the greater the difference between the first dielectric permittivity and the second dielectric permittivity, the easier it can be for the light blocking particles 254b to move into the groove 252c of the first dielectric 252 in the light-transmitting mode. Specifically, in the light controlling panel 200, a voltage can be applied to the first electrode 230 and the second electrode 240 in the light-transmitting mode, and the dielectric polarization can occur in the first dielectric 252 and the solvent 254a of the second dielectric 254. The greater the difference between the first dielectric permittivity and the second dielectric permittivity, the greater the difference in dielectric polarization density at the interface between the first dielectric 252 and the solvent 254a of the second dielectric 254 can be.

The electric field is generated in a direction tilted toward the groove 252c due to the protrusion 253 having inclined side surface disposed on the portion of the top surface of the first dielectric pattern 252a, and the greater the difference in the dielectric polarization density at the interface between the first dielectric 252 and the solvent 254a of the second dielectric 254, the greater the tilt of the electric field direction can be. Accordingly, the plurality of light blocking particles 254b can more easily move into the groove 252c of the first dielectric 252 when switching from the light-blocking mode to the light-transmitting mode.

In one example embodiment, the difference between the first dielectric permittivity and the second dielectric permittivity can be 15 or more. By ensuring that the difference in dielectric permittivity between the first dielectric 252 and the solvent 254a of the second dielectric 254 is greater than or equal to 15, the light control panel 200 can allow the plurality of light blocking particles 254b to move completely into the grooves 252c of the first dielectric 252 in the light-transmitting mode. The light controlling panel 200 can increase light transmittance in light-transmitting mode.

In one example embodiment, the top surface of the first dielectric 252 can be subjected to plasma treatment to have hydrophilicity. The first dielectric 252 can be in direct contact with the solvent 254a of the second dielectric 254 on its top surface. As the dielectric permittivity difference between the first dielectric 252 and the solvent 254a of the second dielectric 254 increases, the adhesion between the first dielectric 252 and the solvent 254a of the second dielectric 254 can decrease. A decrease in the adhesion between the first dielectric 252 and the second dielectric 254 can increase the possibility that the second dielectric 254 is detached from the first dielectric 252. To reduce or prevent this, the first dielectric 252 can be plasma treated so that the top surface of the first dielectric 252 in contact with the solvent 254 of the second dielectric 254 changes from hydrophobicity to hydrophilicity. Through this, the adhesion between the first dielectric 252 and the second dielectric 254, which have a large dielectric permittivity difference, can be improved, and the second dielectric 254 can be reduce or prevented from peeling off from the first dielectric 252.

The plurality of light blocking particles 254b can be negatively or positively charged and distributed within the solvent 254a, and can block light incident from the outside. The plurality of light blocking particles 254b can be an electrophoretic material, for example, carbon particles.

An area where the plurality of light blocking particles 254b are distributed can vary depending on whether the voltage is applied to the first electrode 230 and the second electrode 240. When no voltage is applied to the first electrode 230 and the second electrode 240, the plurality of light blocking particles 254b can be evenly dispersed in the solvent 254a as shown in FIG. 7. Since the plurality of light blocking particles 254b are distributed over the entire area where the solvent 254a is provided, the light-blocking mode can be implemented by external light being blocked by the plurality of light blocking particles 254b over the entire area. The external light does not penetrate the light controlling panel 200 and cannot enter the transmissive area TA as well as the non-transmissive area NTA of the transparent display panel 100.

On the other hand, when the voltage is applied to the first electrode 230 and the second electrode 240, as shown in FIG. 9, the plurality of light blocking particles 254b can be gathered in the groove 252c of the first dielectric 252 along the direction of the electric field. The plurality of light blocking particles 254b can be distributed only in the area where the groove 252c is formed and cannot be distributed in area where the groove 252c is not formed. The external light can be transmitted in area excluding the groove 252c, thereby implementing the light-transmitting mode. The light passing through the light controlling panel 200 can penetrate through the transparent display panel 100 through the transmissive area TA of the transparent display panel 100. Through this, a user located in front surface of the transparent display device 10 can see objects located on the rear surface of the transparent display device 10.

The adhesive layer 260 is disposed between the second electrode 240 and the dielectric layer 250 to adhere the dielectric layer 250 to the second electrode 240. The adhesive layer 260 can be a transparent adhesive film such as optically clear adhesive OCA or a transparent adhesive such as optically clear resin OCR.

The light controlling panel 200 according to an example embodiment of the present disclosure can implement the light-blocking mode and the light-transmitting mode using an electrophoretic element. Through this, the light controlling panel 200 according to an example embodiment of the present disclosure can implement the transparent display device 10 that allows the user to see objects located on the rear surface of the transparent display device 10 in the light-transmitting mode. At the same time, the light controlling panel 200 according to an example embodiment of the present disclosure can enable the transparent display device 10 to display images with a high contrast ratio in the light-blocking mode.

In addition, the light controlling panel 200 according to an example embodiment of the present disclosure can include each of the first electrode 230 and the second electrode 240 as one integral electrode, thereby reducing the cost of processing the electrode and simplifying a driving circuit. In addition, in the light controlling panel 200 according to an example embodiment of the present disclosure, the edge of the electrode is not disposed in the display area DA of the transparent display panel 100, and thus, it is possible to reduce or prevent the plurality of light blocking particles 254b from clumping in an area that overlaps with the display area DA of the transparent display panel 100.

In addition, in the light controlling panel 200 according to an example embodiment of the present disclosure, the top surface of the first dielectric 252 can be formed to have a protrusion 253 protruded toward the second electrode 240 between the two grooves 252c. Through this, in the light controlling panel 200 according to an example embodiment of the present disclosure, when the voltage is applied to the first electrode 230 and the second electrode 240, the plurality of light blocking particles 254b can move into the groove 252c and cannot remain on the top surface of the first dielectric pattern 252a. The light controlling panel 200 according to an example embodiment of the present disclosure can increase light transmittance in the light-transmitting mode.

In addition, in the light controlling panel 200 according to an example embodiment of the present disclosure, the first dielectric pattern 252a of the first dielectric 252 can be disposed to overlap the transmissive area TA of the transparent display panel 100, thereby achieving a high light transmittance in the light-transmitting mode.

In addition, in the light controlling panel 200 according to an example embodiment of the present disclosure, the groove 252c of the first dielectric 252 can be disposed to overlap the non-transmissive area NTA of the transparent display panel 100, so that the light transmittance can be reduce or prevented from decreasing due to the light blocking particles 254b gathered in the groove 252c of the first dielectric 252 in the light-transmitting mode.

In addition, in the light controlling panel 200 according to an example embodiment of the present disclosure, the first dielectric 252 can be formed to have a predetermined thickness in the area where the groove 252c is formed, so that the impact applied when the light blocking particles 254b gather into the groove 252c can be alleviated, thereby reducing or preventing the light blocking particles 254b from being damaged.

In addition, in the light controlling panel 200 according to an example embodiment of the present disclosure, the first dielectric pattern 252a, the spacer 252b, the protrusion 253, and the groove 252c can be formed simultaneously through an imprinting process. Through this, the light controlling panel 200 according to an example embodiment of the present disclosure can reduce the manufacturing process cost and the manufacturing process time due to the simplicity of the manufacturing process, and further reduce the production energy. In addition, the light controlling panel 200 according to an example embodiment of the present disclosure can reduce the manufacturing process and the generation of greenhouse gases due to the manufacturing process can be reduced, thereby improving ESG (Environment/Social/Governance) qualities.

In addition, in the light controlling panel 200 according to an example embodiment of the present disclosure, the difference in dielectric permittivity between the first dielectric 252 and the second dielectric 254 can be large, so that the plurality of light blocking particles 254b can completely move into the groove 252c of the first dielectric 252.

As shown in FIGS. 6 to 10, the light controlling panel 200 according to an example embodiment of the present disclosure can have the first dielectric pattern 252a of the first dielectric 252 aligned with the transmissive area TA of the transparent display panel 100, and the groove 252c of the first dielectric 252 aligned with the non-transmissive area NTA of the transparent display panel 100. However, it is not necessarily limited thereto.

The light controlling panel 200 can be implemented in a film type having flexibility.

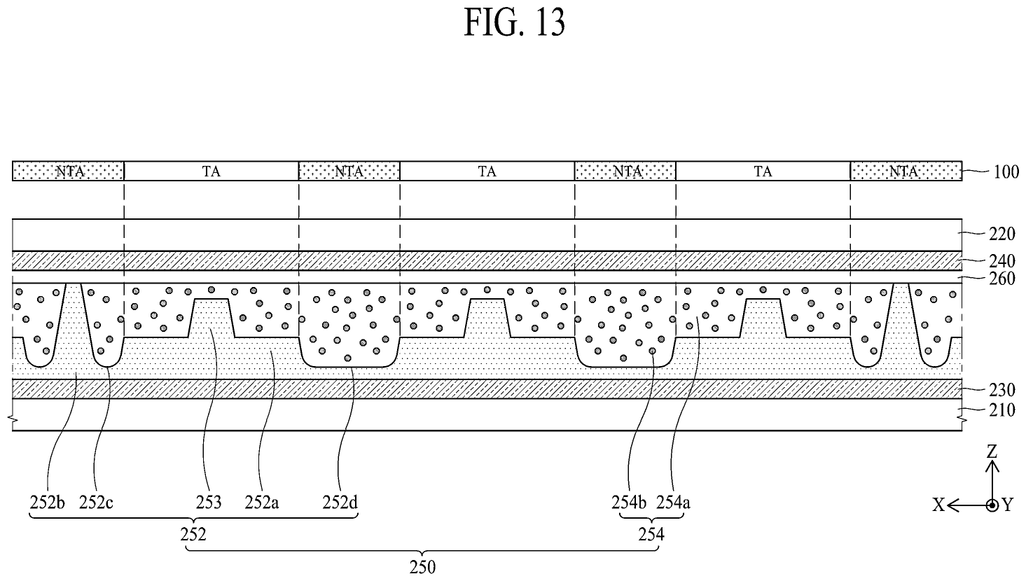

Hereinafter, with reference to FIGS. 13 to 16, a light controlling panel 200 according to another example embodiments of the present disclosure will be described in more detail. The light controlling panel 200 according to another example embodiment of the present disclosure differs only in the dielectric layer 250 compared to the light controlling panel 200 according to an example embodiment of the present disclosure shown in FIGS. 6 to 12B, with the other components being substantially the same. Hereinafter, the differences will be mainly described, and descriptions for substantially the same components will be omitted for brevity. The example embodiments described below can be combined or applied to the structure of an example embodiment of the present disclosure shown in FIGS. 6 to 12.

Referring to FIG. 13, the light controlling panel 200 according to another example embodiment of the present disclosure includes a first substrate 210, a second substrate 220, a first electrode 230, a second electrode 240, a dielectric layer 250, and an adhesive layer 260.

The dielectric layer 250 is disposed between the first electrode 230 and the second electrode 240 to implement the light-blocking mode or the light-transmitting mode depending on whether a voltage is applied to the first electrode 230 and the second electrode 240. For example, the dielectric layer 250 can implement the light-transmitting mode when the voltage is applied to the first electrode 230 and the second electrode 240. On the other hand, the dielectric layer 250 can implement the light-blocking mode when no voltage is applied to the first electrode 230 and the second electrode 240.

The light controlling panel 200 can include a plurality of first dielectric patterns 252a between the adjacent two spacers 252b. A plurality of protrusions 253 can disposed between the adjacent two spacers 252.

One first dielectric pattern 252a can be disposed to correspond to one transmissive area TA, and the second groove 252d can be disposed to correspond to one non-transmissive area NTA.

The spacer 252b can be disposed to correspond to the non-transmissive area NTA. A plurality of transmissive areas TA and non-transmissive NTA can be disposed to correspond to each other in an area between adjacent spacers 252b.

The first dielectric pattern 252a can guide the plurality of light blocking particles 254b included in the second dielectric 254 to the first groove 252c or the second groove 252d. Specifically, the first dielectric pattern 252a can include the protrusion 253 on which a portion of the top surface of the first dielectric pattern 252a protrudes toward the second electrode 240. In this example, the top surface of the first dielectric pattern 252a on which the protrusion 253 is not disposed can be flat. In this case, when the voltage is applied to the first electrode 230 and the second electrode 240, dielectric polarization occurs in the first dielectric material of the first dielectric pattern 252a, and the dielectric polarization density varies depending on the protrusion 253 disposed on the top surface. Accordingly, the electric field can be generated in a direction inclined toward the first groove 252c or the second groove 252d due to the protrusion 253 with a inclined side surface disposed on the top surface of the first dielectric pattern 252a. The protrusion 253 can be disposed on a center of the top surface of the first dielectric pattern 252a.

As a result, in the light controlling panel 200 according to another example embodiment of the present disclosure, when the voltage is applied to the first electrode 230 and the second electrode 240, the plurality of light blocking particles 254b can move to the groove 252c disposed between the first dielectric patterns 252a, and the plurality of light blocking particles 254b cannot be disposed on the top surface of the first dielectric pattern 252a. Accordingly, in the light controlling panel 200 according to another example embodiment of the present disclosure, a light transmittance can be improved in the light-transmitting mode.

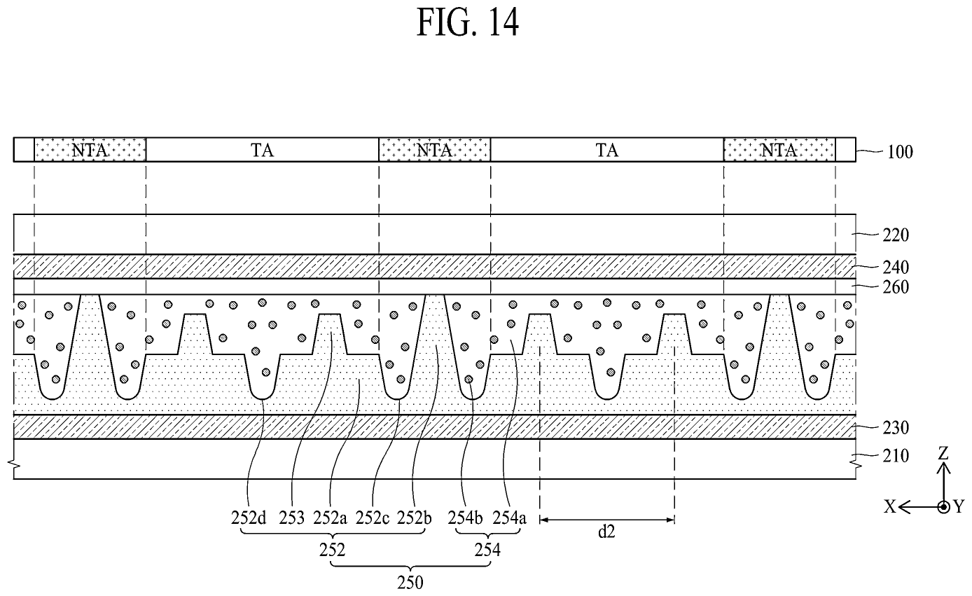

Referring to FIG. 14, the light controlling panel 200 according to another example embodiment of the present disclosure includes a first substrate 210, a second substrate 220, a first electrode 230, a second electrode 240, a dielectric layer 250, and an adhesive layer 260. Hereinafter, detailed descriptions of substantially the same components will be omitted and differences from other example embodiments will be mainly described.

The dielectric layer 250 can include a first dielectric 252 and a second dielectric 254. The first dielectric 252 and the second dielectric 254 can be made of different dielectric materials. The light controlling panel 200 according to another example embodiment of the present disclosure can control the direction of the electric field in a desired direction by utilizing the shape of the interface between the first dielectric 252 and the second dielectric 254 and the difference in dielectric permittivity between the first dielectric 252 and the second dielectric 254. Additionally, the light controlling panel 200 according to another example embodiment of the present disclosure can have a structure that does not require alignment between the components of the first dielectric 252 and the transmissive area TA of the transparent display panel 100.

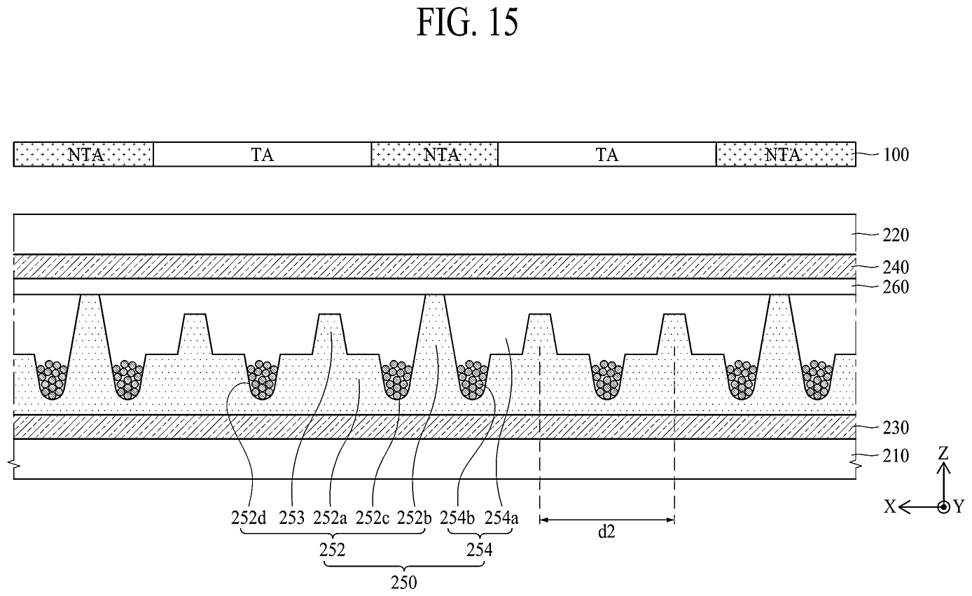

Specifically, the first dielectric 252 is disposed on one side of the first electrode 230 facing the second electrode 240, and can be made of a first dielectric material having a first dielectric permittivity. As shown in FIGS. 14 and 15, the first dielectric 252 can include a first dielectric pattern 252a, a protrusion 253, a spacer 252b, a first groove 252c, and a second groove 252d.

The first dielectric pattern 252a can guide the plurality of light blocking particles 254b included in the second dielectric 254 to the first groove 252c or the second groove 252d. Specifically, the first dielectric pattern 252a can include the protrusion 253 on which a portion of the top surface of the first dielectric pattern 252a protrudes toward the second electrode 240. In this example, the top surface of the first dielectric pattern 252a on which the protrusion 253 is not disposed can be flat. In this case, when the voltage is applied to the first electrode 230 and the second electrode 240, dielectric polarization occurs in the first dielectric material of the first dielectric pattern 252a, and the dielectric polarization density varies depending on the protrusion 253 disposed on the top surface. Accordingly, the electric field can be generated in a direction inclined toward the first groove 252c or the second groove 252d due to the protrusion 253 with a inclined side surface disposed on the top surface of the first dielectric pattern 252a. The protrusion 253 can be disposed on a center of the top surface of the first dielectric pattern 252a.

The plurality of light blocking particles 254b included in the second dielectric 254 can move by the electric field generated between the first electrode 230 and the second electrode 240. When the voltage is applied to the first electrode 230 and the second electrode 240, the plurality of light blocking particles 254b can move to the first groove 252c or the second groove 252d along the direction of the electric field. Accordingly, the plurality of light blocking particles 254b cannot be disposed on the area where first dielectric pattern 252a is disposed, and the area where the first dielectric pattern 252a is disposed can have high light transmittance. Accordingly, external light can be transmitted through the area where the first dielectric pattern 252a is disposed. The light passing through the light controlling panel 200 can be incident on the transparent display panel 100.

In this way, in the light controlling panel 200 according to another example embodiment of the present disclosure, since the protrusion 253 with the inclined side surface can be disposed on top surface of the first dielectric pattern 252a, so that the direction of the electric field can be controlled to face toward the first groove 252c or the second groove 252d when the voltage is applied to the first electrode 230 and the second electrode 240. Accordingly, in the light controlling panel 200 according to another example embodiment of the present disclosure, the plurality of light blocking particles 254b can accurately move to the first groove 252c or the second groove 252d and a high light transmittance can be achieved in light-transmitting mode.

Additionally, in the light controlling panel 200 according to another example embodiment of the present disclosure, the protrusion 253 disposed on the top surface of the first dielectric pattern 252a has the inclined side surface and a flat top surface 252a, thereby reducing or preventing the double image from occurring.

At least a portion of the first dielectric pattern 252a can be disposed to overlap the transmissive area TA of the transparent display panel 100. In the light controlling panel 200 according to another example embodiment of the present disclosure, in the light-transmitting mode, the plurality of light blocking particles 254b can move into the first groove 252c or the second groove 252d and cannot be disposed in the area where the first dielectric pattern 252a is disposed. In the light controlling panel 200 according to another example embodiment of the present disclosure, external light can be transmitted through an area where the plurality of light blocking particles 254b are not disposed, that is, the area where the first dielectric pattern 252a is disposed. Since at least a portion of the first dielectric pattern 252a of the light controlling panel 200 can be disposed to overlap the transmissive area TA of the transparent display panel 100, the light passing through the light controlling panel 200 can pass through the transparent display panel 100 through the transmissive area TA of the transparent display panel 100.

In this way, the external light can penetrate the transparent display device 10 through the area where the first dielectric pattern 252a of the light controlling panel 200 is disposed and the transmissive area TA of the transparent display panel 100. In the transparent display device 10 according to another example embodiment of the present disclosure, at least a portion of the first dielectric pattern 252a of the light controlling panel 200 can be disposed to overlap with the transmissive area TA of the transparent display panel 100, thereby achieving a high light transmittance in the light-transmitting mode.

As shown in FIGS. 14 to 16, in the light controlling panel 200 according to another example embodiment of the present disclosure, one transmissive area TA of the transparent display panel 100 can overlap with a plurality of first dielectric patterns 252a. That is, in the light controlling panel 200 according to another example embodiment of the present disclosure, a plurality of first dielectric patterns 252a can be disposed in an area overlapping one transmissive area TA. Accordingly, the plurality of protrusions 253 can be disposed in an area overlapping one transmissive area TA.

Additionally, in the light controlling panel 200 according to another example embodiment of the present disclosure, a plurality of the first dielectric patterns 252a can be disposed between two adjacent spacers 252b. An area between the adjacent two spacers 252b can be correspond to one transmissive area TA.

For example, two first dielectric patterns 252a can be disposed between the two spacers 252b disposed adjacently as shown in FIGS. 14 to 16, but it is not necessarily limited thereto. Three or more first dielectric patterns 252a can be disposed between two adjacent spacers 252b.

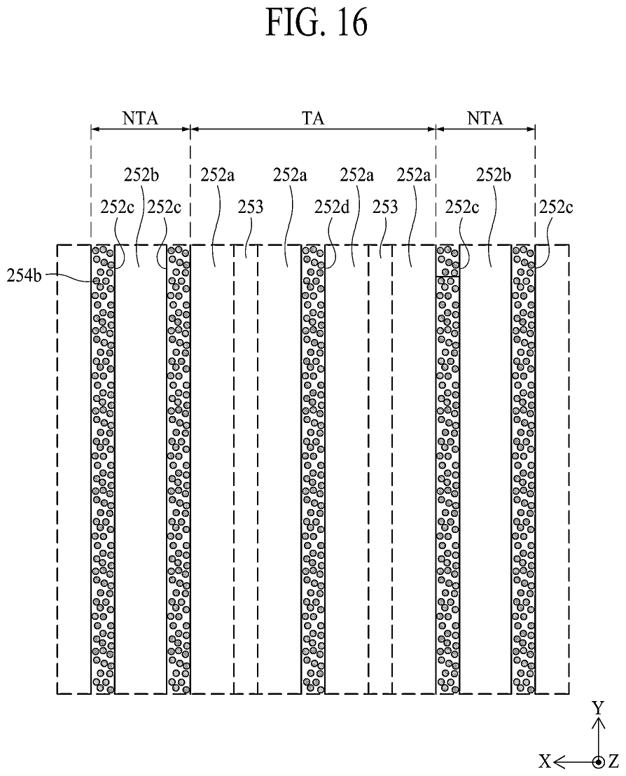

The protrusions 253 and each of the first dielectric patterns 252a can be extended in one direction. In one example embodiment, the first dielectric patterns 252a and the protrusions 253 can be extended parallel to each other in a first direction (e.g., Y-axis direction) as shown in FIG. 16. For example, each of the first dielectric patterns 252a and the protrusions 253 can be extended parallel to the first signal lines SL1. At least a portion of each of the first dielectric patterns 252a and the protrusions 253 is disposed to overlap the transmissive area TA of the transparent display panel 100.

In the light controlling panel 200 according to another example embodiment of the present disclosure, a distance between a center of one first dielectric pattern 252a and a center of the adjacent other first dielectric pattern 252a can be a second distance d2. The second distance d2 can be smaller than the width of the transmissive area TA. In the light controlling panel 200 according to another example embodiment of the present disclosure, the moving distance of the light blocking particles 254b is reduced when switching from the light-blocking mode to the light-transmitting mode, so that the light blocking particles 254b can be better gathered in the grooves 252c and 252d.

The spacer 252b can be disposed between the first electrode 230 and the second electrode 240 to maintain the gap between the first electrode 230 and the second electrode 240. The spacer 252b can be disposed between first dielectric patterns 252a disposed adjacently on a plane.

The first groove 252c can be disposed at (or on) at least one side of the spacer 252b. The first groove 252c can be disposed on the side of the spacer 252b facing the first dielectric pattern 252a. In this example, the spacer 252b can be spaced apart from the first dielectric pattern 252a with the first groove 252c interposed therebetween. For example, the spacer 252b can be disposed between two first dielectric patterns 252a. One first groove 252c can be disposed on one side of the spacer 252b facing one first dielectric pattern 252a, and the spacer 252b can be spaced apart from the one first dielectric pattern 252a with the one first groove 252c interposed therebetween. In addition, another first groove 252c can be disposed on the other side of the spacer 252b facing the other first dielectric pattern 252a, and the spacer 252b can be spaced apart from the other first dielectric pattern 252a with the other first groove 252c interposed therebetween. The spacer 252b can be disposed between the two first grooves 252c.

At least a portion of the spacer 252b can be disposed to overlap the non-transmissive area NTA of the transparent display panel 100. The spacer 252b can be extended in one direction. In one example embodiment, the spacer 252b can be extended in the first direction (e.g., Y-axis direction) as shown in FIG. 16. For example, the spacer 252b can be extended parallel to the first signal lines SL.

The first groove 252c can be disposed between the first dielectric pattern 252a and the spacer 252b, and the second groove 252d can be disposed between adjacent first dielectric patterns 252a. At least a portion of each of the first groove 252c and the second groove 252d can overlap the transmissive area TA of the transparent display panel 100, and the remaining portion can overlap the non-transmissive area NTA of the transparent display panel 100.

The first groove 252c and the second groove 252d are formed concavely toward the first electrode 230, and can gather the light blocking particles 254b included in the second dielectric 254 in light-transmitting mode. When the voltage is applied to the first electrode 230 and the second electrode 240, the plurality of light blocking particles 254b can move into the first groove 252c or the second groove 252d along the direction of the electric field.

Each of the first groove 252c and the second groove 252d can be extended in one direction. In one example embodiment, each of the first groove 252c and the second groove 252d can be extended in the first direction (e.g., Y-axis direction) as shown in FIG. 16. For example, each of the first groove 252c and the second groove 252d can be extended parallel to the first signal lines SL1.

The first groove 252c and the second groove 252d can have different widths. For example, the second groove 252d disposed between the first dielectric patterns 252a can be formed to have a smaller width than the first groove 252c because the second groove 252d has a larger area overlapping with the transmissive area TA of the transparent display panel 100 than the first groove 252c. As a result, the light controlling panel 200 according to another example embodiment of the present disclosure can minimize the reduction in the light transmittance of the transparent display device 10 due to the light blocking particles 254b gathered in the second groove 252d in the light-transmitting mode.

In one example embodiment, the first dielectric pattern 252a, the spacer 252b, the protrusion 253, the first groove 252c, and the second groove 252d included in the first dielectric 252 can be formed as one body. The first dielectric pattern 252a, the spacer 252b, the protrusion 253, the first groove 252c, and the second groove 252d included in the first dielectric 252 can be made of the same first dielectric material. The first dielectric pattern 252a, the spacer 252b, the protrusion 253, the first groove 252c, and the second groove 252d included in the first dielectric 252 can be formed simultaneously through an imprinting process. The light controlling panel 200 according to another example embodiment of the present disclosure simultaneously forms the first dielectric pattern 252a, the spacer 252b, the protrusion 253, the first groove 252c, and the second groove 252d through the imprinting process, thereby reducing the manufacturing process cost and the manufacturing process time due to the simplicity of the manufacturing process, and further reducing the production energy. In addition, the light controlling panel 200 according to another example embodiment of the present disclosure can reduce the manufacturing process and the generation of greenhouse gases due to the manufacturing process can be reduced, thereby improving ESG (Environment/Social/Governance) qualities.

Each of the first dielectric pattern 252a, the spacer 252b, the protrusion 253, the first groove 252c, and the second groove 252d can be imprinted to have different thicknesses on one surface of the first electrode 230. In the light controlling panel 200 according to another example embodiment of the present disclosure, the thicknesses of the first dielectric pattern 252a, the protrusion 253, the spacer 252b, the first groove 252c, and the second groove 252d can be equal to the thicknesses in the example embodiment of the present disclosure described with reference to FIG. 7.

The thickness of the first dielectric 252 in the area where the first groove 252c is disposed can be equal to the thickness of the first dielectric 252 in the area where the second groove 252d is disposed. Here, the thickness of the first dielectric 252 in the area where the first groove 252c is disposed can be a distance from the bottom surface of the first groove 252c to the top surface of the first electrode 230. The thickness of the first dielectric 252 in the area where the second groove 252d is disposed can be a distance from the bottom surface of the second groove 252d to the top surface of the first electrode 230.

Since the light controlling panel 200 according to another example embodiment of the present disclosure includes a first dielectric 252 having a predetermined thickness in the area where the first groove 252c and the second groove 252d are formed, when a voltage is applied to the first electrode 230 and the second electrode 240, the impact applied when the light blocking particles 254b gather into the grooves 252c and 252d can be alleviated, thereby reducing or preventing the light blocking particles 254b from being damaged.

The second dielectric 254 can be disposed on one side of the second electrode 240 facing the first electrode 230. As shown in FIG. 14, the second dielectric 254 can include a solvent 254a and a plurality of light blocking particles 254b.

The solvent 254a is disposed in the first dielectric 252 and can fill the space formed by the step difference among the first dielectric pattern 252a, the protrusion 253, the spacer 252b, the first groove 252c, and the second groove 252d. The solvent 254a can be made of a second dielectric material having a second dielectric permittivity. The second dielectric permittivity can be different from the first dielectric permittivity of the first dielectric material included in the first dielectric 252. In one example embodiment, the second dielectric permittivity can be smaller than the first dielectric permittivity.

Meanwhile, the greater the difference between the first dielectric permittivity and the second dielectric permittivity, the easier it can be for the light blocking particles 254b to move into the grooves 252c and 252d of the first dielectric 252 in the light-transmitting mode. In one example embodiment, the difference between the first dielectric permittivity and the second dielectric permittivity can be 15 or more. By ensuring that the difference in dielectric permittivity between the first dielectric 252 and the solvent 254a of the second dielectric 254 is greater than or equal to 15, the light control panel 200 can allow the plurality of light blocking particles 254b to move completely into the grooves 252c and 252d of the first dielectric 252 in the light-transmitting mode. The light controlling panel 200 can increase light transmittance in light-transmitting mode.

In one example embodiment, the top surface of the first dielectric 252 can be subjected to plasma treatment to have hydrophilicity. The first dielectric 252 can be plasma treated so that the top surface of the first dielectric 252 in contact with the solvent 254 of the second dielectric 254 changes from hydrophobicity to hydrophilicity. Through this, the adhesion between the first dielectric 252 and the second dielectric 254, which have a large dielectric permittivity difference, can be improved, and the second dielectric 254 can be reduced or prevented from peeling off from the first dielectric 252.

The plurality of light blocking particles 254b can be negatively or positively charged and distributed within the solvent 254a, and can block light incident from the outside. The plurality of light blocking particles 254b can be an electrophoretic material, for example, carbon particles.

An area where the plurality of light blocking particles 254b are distributed can vary depending on whether the voltage is applied to the first electrode 230 and the second electrode 240. When no voltage is applied to the first electrode 230 and the second electrode 240, the plurality of light blocking particles 254b can be evenly dispersed in the solvent 254a as shown in FIG. 14. Since the plurality of light blocking particles 254b are distributed over the entire area where the solvent 254a is provided, the light-blocking mode can be implemented by external light being blocked by the plurality of light blocking particles 254b over the entire area. The external light does not penetrate the light controlling panel 200 and cannot enter the transmissive area TA as well as the non-transmissive area NTA of the transparent display panel 100.

On the other hand, when the voltage is applied to the first electrode 230 and the second electrode 240, as shown in FIGS. 15 and 16, the plurality of light blocking particles 254b can be gathered in the grooves 252c and 252d of the first dielectric 252 along the direction of the electric field. The plurality of light blocking particles 254b can be distributed only in the area where the grooves 252c and 252d are formed and cannot be distributed in area where the grooves 252c and 252d are not formed. The external light can be transmitted in area excluding the grooves 252c and 252d, thereby implementing the light-transmitting mode. The light passing through the light controlling panel 200 can penetrate through the transparent display panel 100 through the transmissive area TA of the transparent display panel 100. Through this, a user located in front surface of the transparent display device 10 can see objects located on the rear surface of the transparent display device 10.

The light controlling panel 200 according to another example embodiment of the present disclosure can implement the light-blocking mode and the light-transmitting mode using an electrophoretic element. Through this, the light controlling panel 200 according to another example embodiment of the present disclosure can implement the transparent display device 10 that allows the user to see objects located on the rear surface of the transparent display device 10 in the light-transmitting mode. At the same time, the light controlling panel 200 according to another example embodiment of the present disclosure can enable the transparent display device 10 to display images with a high contrast ratio in the light-blocking mode.

In addition, the light controlling panel 200 according to another example embodiment of the present disclosure can include each of the first electrode 230 and the second electrode 240 as one integral electrode, thereby reducing the cost of processing the electrode and simplifying a driving circuit. In addition, in the light controlling panel 200 according to another example embodiment of the present disclosure, the edge of the electrode is not disposed in the display area DA of the transparent display panel 100, and thus, it is possible to reduce or prevent the plurality of light blocking particles 254b from clumping in an area that overlaps with the display area DA of the transparent display panel 100.

In addition, in the light controlling panel 200 according to another example embodiment of the present disclosure, the protrusion 253 can be disposed on the top surface of the first dielectric pattern 252a of the first dielectric 252, the protrusion 253 can be protruded between the two grooves 252c and 252d toward the second electrode 240, and the protrusion 253 can have the inclined side surface and the flat top surface. Through this, in the light controlling panel 200 according to another example embodiment of the present disclosure, when the voltage is applied to the first electrode 230 and the second electrode 240, the plurality of light blocking particles 254b can quickly move into the grooves 252c and 252d and cannot remain on the top surface of the first dielectric pattern 252a. The light controlling panel 200 according to another example embodiment of the present disclosure can increase light transmittance in the light-transmitting mode.

In addition, in the light controlling panel 200 according to another example embodiment of the present disclosure, at least a portion of the first dielectric pattern 252a of the first dielectric 252 can be disposed to overlap the transmissive area TA of the transparent display panel 100, thereby achieving a high light transmittance in the light-transmitting mode.

In addition, in the light controlling panel 200 according to another example embodiment of the present disclosure, at least a portion of each of the grooves 252c and 252d of the first dielectric 252 can be disposed to overlap the non-transmissive area NTA of the transparent display panel 100, so that the light transmittance can be reduced or prevented from decreasing due to the light blocking particles 254b gathered in the grooves 252c and 252d of the first dielectric 252 in the light-transmitting mode.

In addition, in the light controlling panel 200 according to another example embodiment of the present disclosure, the width of the first dielectric pattern 252a can be reduced and the second groove 252d can be disposed between the first dielectric patterns 252a. The second groove 252d can be disposed to correspond to the transmissive area TA.

Since the light controlling panel 200 according to another example embodiment of the present disclosure include the second groove 252d, the amount of the light blocking particles 254b to be gathered in the first groove 252c disposed between the first dielectric pattern 252a and the spacer 252b can be reduced, and thus, the width of the first groove 252c can be reduced. Accordingly, it can be easier for the light controlling panel 200 according to another example embodiment of the present disclosure to align the first groove 252c within the non-transmissive area NTA of the transparent display panel 100. That is, the light controlling panel 200 according to another example embodiment of the present disclosure can align the first groove 252c within the non-transmissive area NTA of the transparent display panel 100 even if a slight process error occurs.

In the light controlling panel 200 according to another example embodiment of the present disclosure, the first groove 252c cannot be completely aligned within the non-transmissive area NTA of the transparent display panel 100 due to a process error. However, even in this case, in the light controlling panel 200 according to another example embodiment of the present disclosure, the light blocking particles 254b are also dispersed in the second groove 252d, thereby reducing or preventing the transmittance from being greatly reduced in only some areas in the light-transmitting mode and achieving uniform transmittance.

In addition, in the light controlling panel 200 according to another example embodiment of the present disclosure, the difference in dielectric permittivity between the first dielectric 252 and the second dielectric 254 can be large, so that the plurality of light blocking particles 254b can completely move into the grooves 252c and 252d of the first dielectric 252, thereby improving the light transmittance in the light-transmitting mode.

In one or more example embodiments of the present disclosure, the light-blocking mode and the light-transmitting mode can be selectively implemented. Thus, the transparent display device according to one or more example embodiments of the present disclosure can allow a user to clearly see objects and background scenes located on the rear surface of the transparent display device in the light-transmitting mode, and can also block external light from penetrating into the transparent display device to display images having a high contrast to the user in the light-blocking mode.

Moreover, in one or more example embodiments of the present disclosure, each of the electrodes provided in the light controlling panel as an integral electrode, thereby reducing the cost of processing the electrode and simplifying a driving circuit.

Moreover, in one or more example embodiments of the present disclosure, since the edge of the electrode is not disposed in the display area of the transparent display panel, it is possible to reduce or prevent a plurality of light blocking particles from clumping in the area overlapping the display area of the transparent display panel.

Moreover, in one or more example embodiments of the present disclosure, since the upper surface of the first dielectric pattern of the first dielectric have a protrusion, the plurality of light blocking particles move into the groove and do not remain on the upper surface of the first dielectric pattern in the light-transmitting mode, thereby increasing the light transmittance in the light-transmitting mode.

Moreover, in one or more example embodiments of the present disclosure, the first dielectric pattern of the first dielectric can be disposed to overlap with the transmissive area of the transparent display panel, thereby obtaining a high light transmittance when the transparent display device is operated in the light-transmitting mode.

Moreover, in one or more example embodiments of the present disclosure, the groove of the first dielectric can be disposed to overlap with a non-transmissive area of the transparent display panel, thereby reducing or preventing the light transmittance of the transparent display device from being reduced due to light blocking particles gathered in the groove of the first dielectric when the transparent display device is operated in the light-transmitting mode.

Moreover, in one or more example embodiments of the present disclosure, since the first dielectric can be formed to have a predetermined thickness in an area where the groove is formed, the impact applied when the light blocking particles gather into the groove can be alleviated, thereby reducing or preventing the light blocking particles from being damaged.

Moreover, in one or more example embodiments of the present disclosure, a dielectric permittivity difference between the first dielectric and the second dielectric can be large, the plurality of light blocking particles can perfectly move into the groove of the first dielectric.

Moreover, in one or more example embodiments of the present disclosure, the first dielectric pattern, the spacer, and the groove can be simultaneously formed through an imprinting process, thereby reducing the manufacturing process cost and the manufacturing process time due to the simplicity of the manufacturing process, and further reducing the production energy.

Moreover, in one or more example embodiments of the present disclosure, the manufacturing process for producing the transparent display devices can be reduced and the generation of greenhouse gases due to the manufacturing process can be reduced, thereby improving ESG (Environment/Social/Governance) qualities.

In one or more example embodiments of the present disclosure, a transparent display can comprise a transparent display panel including a transmissive area for transmitting an external light and a non-transmissive area at which a plurality of pixels are disposed, and a light controlling panel including a dielectric layer, wherein the dielectric layer comprises a plurality of light blocking particles that are movable, wherein the light controlling panel is configured to operate in a light-blocking mode or a light-transmitting mode, and wherein for the light-transmitting mode, the light controlling panel is configured to cause the plurality of light blocking particles to move into an area corresponding to the non-transmissive area.

Moreover, in one or more example embodiments of the present disclosure, for the light-transmitting mode, the light controlling panel is configured to cause all of the plurality of light blocking particles to move into the area corresponding to the non-transmissive area, with none of the plurality of light blocking particles for being in an area corresponding to the transmissive area, and for the light-blocking mode, the light controlling panel is configured to cause the plurality of light blocking particles to be present in areas corresponding to the non-transmissive area and the transmissive area.

Moreover, in one or more example embodiments of the present disclosure, the light controlling panel further includes a first electrode and a second electrode, the dielectric layer is disposed between the first electrode and the second electrode, and in accordance with whether a voltage is for being applied to the first electrode and the second electrode, the light controlling panel is configured operate in the light-blocking mode or the light-transmitting mode.

In one or more examples, an element may include or may be one or more elements. In one or more examples, an element may include a plurality of elements. In one or more examples, a transmissive area may be one or more transmissive areas. In one or more examples, a transmissive area may include a plurality of transmissive areas. In one or more examples, a non-transmissive area may be one or more non-transmissive areas. In one or more examples, a non-transmissive area may include a plurality of non-transmissive areas. In one or more examples, an area may be one or more areas. In one or more examples, an area may include a plurality of areas.

The above-described feature, structure, and effect of the present disclosure are included in at least one example embodiment of the present disclosure, but are not limited to only one example embodiment. Furthermore, the feature, structure, and effect described in at least one example embodiment of the present disclosure can be implemented through a combination or modification of other example embodiments by those skilled in the art. Therefore, content associated with the combination and modification should be construed as being within the scope of the present disclosure.

It will be apparent to those skilled in the art that various modifications and variations can be made in one or more example embodiments of the present disclosure without departing from the spirit or scope of the present disclosure. Thus, it is intended that the present disclosure covers the modifications and variations of this present disclosure.

The various example embodiments described above can be combined to provide further example embodiments.

These and other changes can be made to the example embodiments in light of the present disclosure. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the present disclosure.

What is claimed is:

1. A light controlling panel, comprising:
a first electrode and a second electrode disposed to face each other; and
a dielectric layer disposed between the first electrode and the second electrode,
wherein the dielectric layer comprises:
a first dielectric including a first dielectric material and a groove, the first dielectric material having a first dielectric permittivity; and
a second dielectric including a plurality of light blocking particles and a solvent including a second dielectric material having a second dielectric permittivity less than the first dielectric permittivity,
wherein the first dielectric comprises a first dielectric pattern disposed between adjacent grooves, and
wherein the first dielectric further comprises a protrusion where a portion of a top surface of the first dielectric pattern protrudes toward the second electrode.

2. The light controlling panel of claim 1, wherein the protrusion has an inclined side surface of a regular tapered shape.

3. The light controlling panel of claim 1, wherein the protrusion has a flat top surface.

4. The light controlling panel of claim 1, wherein a horizontal distance between a first point of the top surface of the first dielectric pattern and a second point of a top surface of the protrusion is less than a vertical distance which is a height of the protrusion,
wherein the first point is a point where the top surface of the first dielectric pattern and one end of a side surface of the protrusion meet, and
wherein the second point is a point where the top surface of the protrusion and the other end of the side surface of the protrusion meet.

5. The light controlling panel of claim 1, wherein the first dielectric pattern, the protrusion, and the groove is disposed as a single body.

6. The light controlling panel of claim 1, wherein a difference between the first dielectric permittivity and the second dielectric permittivity is equal to or greater than 15.

7. The light controlling panel of claim 1, wherein the first dielectric further comprises a spacer maintaining a gap between the first electrode and the second electrode, and
wherein the groove is disposed at at least one side of the spacer.

8. The light controlling panel of claim 7, wherein the groove is disposed between the first dielectric pattern and the spacer, and
the groove is disposed between adjacent first dielectric patterns.

9. The light controlling panel of claim 7, wherein the first dielectric pattern, the protrusion, the groove, and the spacer are disposed as a single body.

10. The light controlling panel of claim 1, wherein the first dielectric pattern is extended in a first direction,
wherein the protrusion is extended in the first direction on the top surface of the first dielectric pattern, and
wherein the groove is extended in the first direction parallel to the first dielectric pattern or the protrusion.

11. The light controlling panel of claim 1, wherein the first dielectric is disposed on a top surface of the first electrode, and
wherein the first dielectric has a first thickness in an area where the groove is disposed.

12. The light controlling panel of claim 1, wherein each of the first electrode and the second electrode is a transparent electrode, and
wherein the first electrode or the second electrode is disposed to correspond to a plurality of protrusions.

13. A transparent display device, comprising:
a transparent display panel including a transmissive area for transmitting an external light and a non-transmissive area in which a plurality of pixels are disposed; and
a light controlling panel including a first electrode, a second electrode, and a dielectric layer disposed between the first electrode and the second electrode,
wherein the dielectric layer comprises:
a first dielectric including a first dielectric material having a first dielectric permittivity, the first dielectric further including a groove; and
a second dielectric including a plurality of light blocking particles and a solvent including a second dielectric material having a second dielectric permittivity less than the first dielectric permittivity,
wherein the first dielectric comprises a first dielectric pattern disposed between adjacent grooves, and
wherein the first dielectric further comprises a protrusion where a portion of a top surface of the first dielectric pattern protrudes toward the second electrode.

14. The transparent display device of claim 13, wherein the protrusion has an inclined side surface of a regular tapered shape.

15. The transparent display device of claim 13, wherein the protrusion has a flat top surface.

16. The transparent display device of claim 13, wherein a horizontal distance between a first point of the top surface of the first dielectric pattern and a second point of a top surface of the protrusion is less than a vertical distance which is a height of the protrusion,
wherein the first point is a point where the top surface of the first dielectric pattern and one end of a side surface of the protrusion meet, and
wherein the second point is a point where the top surface of the protrusion and the other end of the side surface of the protrusion meet.

17. The transparent display device of claim 13, wherein the first dielectric pattern, the protrusion, and the groove is disposed as a single body.

18. The transparent display device of claim 13, wherein the first dielectric pattern and the protrusion are disposed in an area corresponding to the transmissive area.

19. The transparent display device of claim 13, wherein the first dielectric pattern and the protrusion are extended in a first direction in an area corresponding to the transmissive area, and
wherein the groove is extended, in the first direction parallel to at least one of the first dielectric pattern or the protrusion, in an area corresponding to the non-transmissive area.

20. The transparent display device of claim 13, wherein a plurality of protrusions are disposed in an area corresponding to the transmissive area, and
at least one groove is disposed between two adjacent first dielectric patterns.

21. The transparent display device of claim 13, wherein the first dielectric further comprises a spacer maintaining a gap between the first electrode and the second electrode,
wherein the groove is disposed at least one side of the spacer, and
wherein the spacer and the groove are disposed in an area corresponding to the non-transmissive area.

22. The transparent display device of claim 21, wherein a plurality of first dielectric patterns and a plurality of protrusions are disposed between adjacent spacers.

23. The transparent display device of claim 13, wherein the transparent display panel further comprises a light emitting device and a color filter disposed on the light emitting device, and
wherein the groove is disposed to overlap the light emitting device and the color filter.

24. A transparent display device, comprising:
a transparent display panel including a transmissive area for transmitting an external light and a non-transmissive area at which a plurality of pixels are disposed; and
a light controlling panel including a dielectric layer,
wherein:
the dielectric layer comprises a plurality of light blocking particles that are movable;
the light controlling panel is configured to operate in a light-blocking mode or a light-transmitting mode; and
for the light-transmitting mode, the light controlling panel is configured to cause the plurality of light blocking particles to move into an area corresponding to the non-transmissive area.

25. The transparent display device of claim 24, wherein:
for the light-transmitting mode, the light controlling panel is configured to cause all of the plurality of light blocking particles to move into the area corresponding to the non-transmissive area, with none of the plurality of light blocking particles for being in an area corresponding to the transmissive area; and
for the light-blocking mode, the light controlling panel is configured to cause the plurality of light blocking particles to be present in areas corresponding to the non-transmissive area and the transmissive area.

26. The transparent display device of claim 24, wherein:
the light controlling panel further includes a first electrode and a second electrode;
the dielectric layer is disposed between the first electrode and the second electrode; and
in accordance with whether a voltage is for being applied to the first electrode and the second electrode, the light controlling panel is configured operate in the light-blocking mode or the light-transmitting mode.
